(19) United States
(12) Patent Application Publication
(10) Pub. No.: US 2026/0026164 A1
(43) Pub. Date: Jan. 22, 2026

(54) Display Device and Manufacturing Method Thereof

(71) Applicant: LG Display Co., Ltd., Seoul (KR)

(72) Inventors: Hyun Ho Lee, Paju-si (KR); Dong Kwan Hyun, Paju-si (KR); Hyoung Sun Park, Paju-si (KR)

(21) Appl. No.: 19/220,009

(22) Filed: May 27, 2025

(30) Foreign Application Priority Data
Jul. 19, 2024 (KR) 10-2024-0095764

(51) Int. Cl. H10H 29/49; H10H 29/37; H10H 29/41; H10H 29/80; H10K 59/122; H10K 59/124; H10K 59/131; H10K 59/80; H10K 102/10

(52) U.S. Cl. CPC H10H 29/49; H10H 29/37; H10H 29/41; H10H 29/8323; H10K 59/122; H10K 59/124; H10K 59/131; H10K 59/80523; H10K 59/80524; H10K 2102/102; H10K 2102/103

(57) ABSTRACT

Disclosed are a display device and a manufacturing method thereof. The display device may comprise a substrate having a display region and a non-display region outside the display region; a circuit layer including a plurality of lines disposed on the substrate, wherein the plurality of lines are separated with a first insulating layer therebetween; and an second insulating layer including a first contact hole that exposes an uppermost layer line in the display region and a second contact hole that exposes an uppermost layer line in the non-display region, wherein a thickness of the second insulating layer in the non-display region is different from a thickness of the second insulating layer in the display region.

### CROSS-REFERENCE TO RELATED APPLICATION

This application claims priority and the benefit of Republic of Korea Patent Application No. 10-2024-0095764, filed on Jul. 19, 2024, which is hereby incorporated by reference in its entirety.

### BACKGROUND

### Technical Field

The present disclosure relates to a display device, and more specifically, for example, without limitation, to a display device capable of reducing damage to a connection line and residual film and reducing corrosion problems of a pad by adding an insulating layer to a pad portion and a manufacturing method thereof.

### Discussion of Related Art

Display devices include an organic light-emitting display (OLED) device which emits light by itself, a liquid crystal display (LCD) device which requires a separate light source, and the like.

Recently, display devices including light-emitting elements (light-emitting diodes, LEDs) are attracting attention as next generation display devices. The light-emitting elements are formed of an inorganic material rather than an organic material, and thus the display devices including light-emitting elements may have a faster lighting speed and higher luminous efficacy and display higher brightness images compared to a LCD device or OLED device.

### SUMMARY

The inventor has realized that in the related art, a connection line and a pad portion in the display device is easily damaged. Accordingly, an exemplary embodiment of the present disclosure is directed to providing a display device capable of improving damage to a connection line and residual film and corrosion problems of a pad by adding an insulating layer to a pad portion, and minimizing the problem of conductive ball pressing by forming a thickness of the insulating layer to be thinner than that of an insulating layer of a display region.

The objects according to exemplary embodiments of the present disclosure are not limited to the above-described objects, and other objects that are not mentioned will be clearly understood by those skilled in the art from the following description.

A display device according to an exemplary embodiment of the present disclosure includes: a substrate having a display region and a non-display region outside the display region; a circuit layer including a plurality of lines disposed on the substrate and separated with a first insulating layer therebetween; and a second insulating layer including a first contact hole that exposes an uppermost layer line in the display region and a second contact hole that exposes an uppermost layer line in the non-display region, wherein a thickness of the second insulating layer in the non-display region is smaller than a thickness of the second insulating layer in the display region.

A display device according to an exemplary embodiment of the present disclosure includes: a substrate having a display region and a non-display region outside the display region; and a circuit layer including a plurality of lines disposed on the substrate, the plurality of lines being separated with a first insulating layer therebetween, wherein a thickness of a second insulating layer that covers an uppermost layer line among the plurality of lines varies between the display region and the non-display region.

A manufacturing method of a display device according to an exemplary embodiment of the present disclosure includes: forming a substrate having a display region and a non-display region outside the display region; forming a circuit layer including a plurality of lines on the substrate, the plurality of lines being separated with a first insulating layer therebetween; and forming a second insulating layer above the plurality of lines, and the second insulating layer including a first contact hole that exposes an uppermost layer line in the display region and a second contact hole that exposes an uppermost layer line in the non-display region, wherein a thickness of the second insulating layer in the non-display region is different from a thickness of the second insulating layer in the display region.

A manufacturing method of a display device according to an exemplary embodiment of the present disclosure includes: forming a substrate having a display region and a non-display region outside the display region; and forming a circuit layer including a plurality of lines on the substrate, the plurality of lines being separated with a first insulating layer therebetween, wherein a thickness of a second insulating layer that covers an uppermost layer line among the plurality of lines varies between the display region and the non-display region.

Specific details according to the various examples of the present disclosure other than solutions to the above-mentioned problems are included in the description and drawings described below.

### BRIEF DESCRIPTION OF THE DRAWINGS

The following drawings attached to this disclosure illustrate preferred exemplary embodiments of the present invention and, together with the detailed description of the invention to be described below, serve to further understand the technical idea of the present invention, and therefore the present invention should not be construed as being limited to matters described in such drawings, in which:

FIG. 1 is an exploded perspective view of a display device according to an exemplary embodiment of the present disclosure;

FIG. 2 is a plan view of the display device according to an exemplary embodiment of the present disclosure;

FIG. 3 is an enlarged plan view of a connection structure of the display device according to an exemplary embodiment of the present disclosure;

FIG. 4 is a view showing a circuit structure according to an exemplary embodiment of the present disclosure;

FIG. 5 is a plan view of the display device according to an exemplary embodiment of the present disclosure;

FIG. 6 is a plan view of the display device according to an exemplary embodiment of the present disclosure;

FIG. 7 is a plan view of the display device according to an exemplary embodiment of the present disclosure;

FIG. 8 is a cross-sectional view of the display device taken along line I-I′ in FIG. 2 according to an exemplary embodiment of the present disclosure;

FIG. 9 is an enlarged cross-sectional view of the display device according to an exemplary embodiment of the present disclosure;

FIG. 10 is a cross-sectional view of a display device taken along line I-I′ in FIG. 2 according to one exemplary embodiment of the present disclosure;

FIG. 11 is an enlarged cross-sectional view of a pad portion of the display device according to one exemplary embodiment of the present disclosure;

FIG. 12 is a cross-sectional view of a display device taken along line II-II′ in FIG. 10 according to another exemplary embodiment of the present disclosure;

FIG. 13 is an enlarged cross-sectional view of a pad portion of the display device according to another exemplary embodiment of the present disclosure;

FIG. 14 is a flowchart of a display device manufacturing process according to the exemplary embodiment of the present disclosure;

FIGS. 15A to 15D are cross-sectional views of a display device manufacturing process according to one exemplary embodiment of the present disclosure; and

FIGS. 16 to 19 are views showing devices to which the display device according to exemplary embodiments of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and methods of achieving them will become apparent with reference to the following embodiments, which are described in detail, in conjunction with the accompanying drawings. However, the present disclosure is not limited to the embodiments to be described below and may be implemented in various different forms, the embodiments are only provided to completely disclose the present disclosure and completely convey the scope of the present disclosure to those skilled in the art.

Since the shapes, sizes, dimensions (e.g., length, width, height, thickness, radius, diameter, area, etc.), ratios, angles, numbers, and the like disclosed in the drawings for describing the embodiments of the present disclosure are only exemplary, the present disclosure is not limited to the items shown in the drawings.

A dimension including a size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference number indicates the same components throughout the disclosure. Further, in describing the present disclosure, when it is determined that a detailed description of related known technology may unnecessarily obscure the gist of the present disclosure, the detailed description thereof will be omitted. When “include,” “have,” “comprise,” “contain,” “constitute,” “make up of,” “formed of,” and “consist of” and the like are used herein, other parts may be added unless ‘only’ is used. A case in which a component is expressed in a singular form may include a plural form unless explicitly stated otherwise.

In interpreting a component, the component is interpreted as including a margin of error even when there is no separate explicit description of the margin of error.

In a description of a positional relationship, when the positional relationship of two parts such as “on”, “above”, “over”, “below”, “under”, “beside”, “beneath”, “near”, “close to,” “adjacent to”, “on a side of”, “next” or the like is described, one or more other parts may be located between two components unless “immediately”, “directly,” “close to” is used.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

In a description of a temporal relationship, when the temporal relationship is described as “after,” “following,” “and then,” “before,” or the like, non-consecutive cases may also be included unless “immediately” or “directly” is used.

Although first, second, and the like are used to describe various components, these components are not limited by these terms. These terms are only used to distinguish one component from another component. Accordingly, a first component described below may also be a second component within the technical spirit of the present disclosure.

Terms, such as first, second, A, B, (a), and (b) may be used to describe components of the present disclosure. These terms are only for the purpose of distinguishing one component from another component, and the nature, sequence, order, or the like of the corresponding components is not limited by these terms.

When a component is described as being “connected,” “coupled,” “linked,” or “attached” to another component, it should be understood that the component may be directly connected, coupled, linked, or attached to the other component, but another component may be interposed between the components which may be indirectly connected, coupled, linked, or attached to each other unless explicitly stated otherwise.

When a component or layer is described as “being in contact with” or “overlapping” another component or layer, it should be understood that the component or layer may be in direct contact with or directly overlap another component or layer, but another component may be interposed between the components which may be in direct contact with or directly overlap each other unless explicitly stated otherwise.

“At least one” should be understood as including a combination of one or more of the related components. For example, the term “at least one of first, second, and third components” includes not only the first, second, or third component, but also all combinations of two or more of the first, second, and third components.

The terms “first direction,” “second direction,” “third direction,” “X-axis direction,” “Y-axis direction,” and “Z-axis direction” should not be understood as only a geometric relationship in which a relationships therebetween are perpendicular to each other, but mean that a configuration of the present disclosure has a broader directionality within a range in which it may functionally act.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Features of various exemplary embodiments of the present disclosure may be partially or entirely combined with each other, and technically, various linkages and operations are possible, and the exemplary embodiments may be implemented independently of each other or together in a related relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the embodiments of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, various exemplary embodiments of the present disclosure will be described in detail with reference to the accompanying drawings.

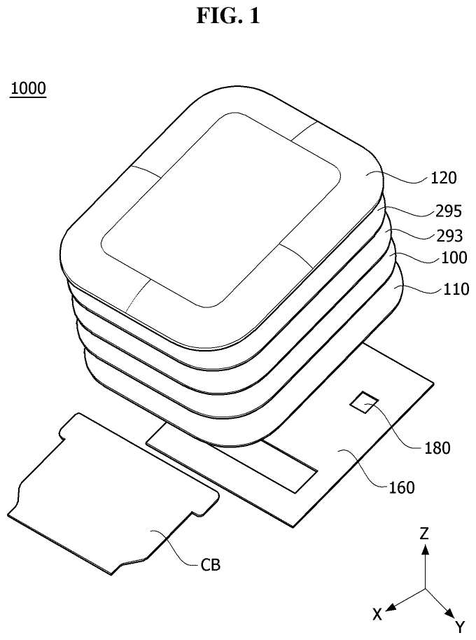

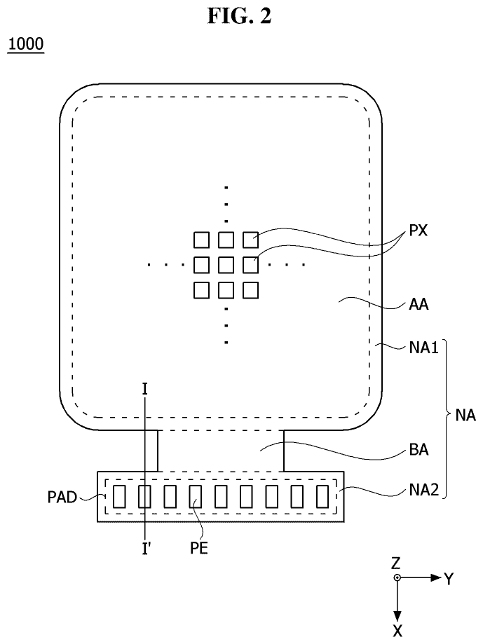

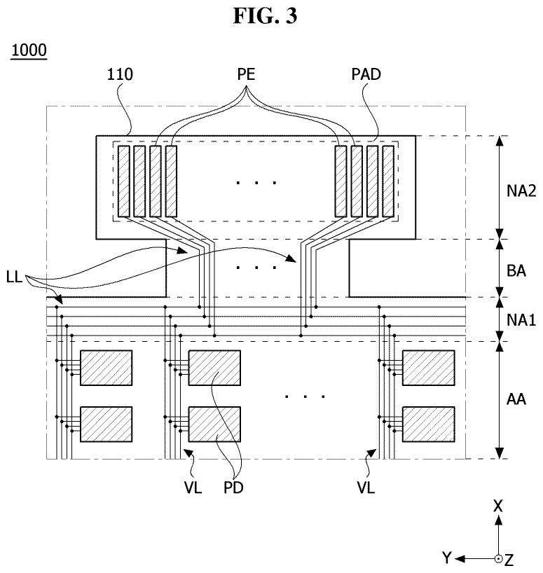

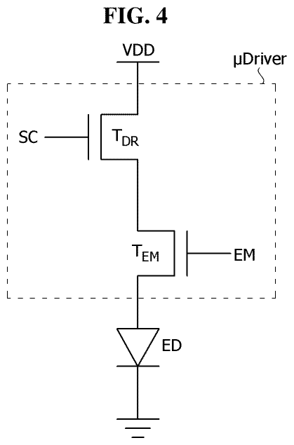

FIG. 1 is an exploded perspective view of a display device according to an exemplary embodiment of the present disclosure. FIG. 2 is a plan view of the display device according to an exemplary embodiment of the present disclosure. FIG. 3 is an enlarged plan view of a connection structure of the display device according to an exemplary embodiment of the present disclosure. FIG. 4 is a view showing a circuit structure according to an exemplary embodiment of the present disclosure.

Referring to FIGS. 1 to 3, a display device 1000 according to the exemplary embodiment of the present disclosure may include a display panel 100, a polarization layer 293, an adhesive layer 295, a cover member 120, a substrate 110, a flexible circuit board CB, and a printed circuit board 160.

For example, the display device 1000 may include the substrate 110. The substrate 110 may be a member which supports other components of the display device 1000. The substrate 110 may be formed of an insulating material. For example, the substrate 110 may be formed of glass, a resin, or the like. Further, the substrate 110 may be formed of a material having flexibility. For example, the substrate may include a flexible polymer film. For example, the flexible polymer film may be made of any one of polyimide (PI), polyethylene terephthalate (PET), acrylonitrile-butadiene-styrene copolymer(ABS), polymethyl methacrylate (PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS), and the present disclosure is not limited thereto. For example, the substrate 110 may be a film formed of a plastic material film having flexibility such as polyimide (PI) or the like. However, the exemplary embodiments of the present disclosure are not limited thereto.

The display panel 100 may have a width in a Y-axis direction, a length in a X-axis direction, and a thickness in a Z-axis direction, but not limited thereto. For example, the display panel 100 may have a width in an X-axis direction, a length in a Y-axis direction, and a thickness in a Z-axis direction. The X-axis direction and the Y-axis direction may intersect each other on the plane of the display panel 100. For example, the X-axis direction and the Y-axis direction may be orthogonal to each other, but not limited thereto.

The display panel 100 may implement information, a video, and/or an image provided to a user. For example, the display panel 100 may include a display region AA and a non-display region NA. For example, the substrate 110 may include the display region AA and the non-display region NA. The display region AA and the non-display region NA are not limited to the substrate 110 but may be provided throughout the display device 1000.

The display region AA may be a region where an image is displayed. The display region AA may include a plurality of pixels PX. Each of the plurality of subpixels is a minimum unit which configures the display region and n subpixels form one pixel. Each of the plurality of subpixels may emit light having different wavelengths from each other. The plurality of subpixels may include first to third subpixels which emit different color light from each other. For example, the sub-pixels may include red, green, and blue sub-pixels. Meanwhile, the sub-pixels may also include white sub-pixel. The plurality of subpixels may be variously modified in colors and configurations, as necessary. However, the present disclosure is not limited thereto.

For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

Each of the plurality of pixels PX may be composed of a plurality of subpixels. A plurality of light-emitting elements may be disposed in each of the plurality of subpixels. The plurality of light-emitting elements may be configured differently depending on the type of display device 1000. For example, when the display device 1000 is an inorganic light-emitting display device, the light-emitting element may be an inorganic light-emitting diode (LED), a micro light-emitting diode (micro LED), or a mini light-emitting diode (mini LED), but the exemplary embodiments of the present disclosure are not limited thereto.

The non-display region NA may be a region where an image is not displayed. The non-display region NA may be placed outside the display region AA. For example, the non-display region NA may be an area adjacent to the display region DA. Further, the non-display region NA may be an area disposed adjacent to the display region AA and configured to surround the display region DA. Various lines and circuits for driving the plurality of pixels PX of the display region AA may be disposed in the non-display region NA. For example, in the non-display region NA, various lines and driving circuits may be mounted, and a pad portion PAD to which an integrated circuit, a printed circuit, and the like are connected may be disposed, but the exemplary embodiments of the present disclosure are not limited thereto.

For example, the driving circuit may be a data driving circuit and/or a gate driving circuit, but the exemplary embodiments of the present disclosure are not limited thereto. Lines through which control signals for controlling the driving circuits are supplied may be disposed on the display panel 100. For example, the control signals may include various timing signals including a clock signal, an input data enable signal, and a synchronization signal (for example, a horizontal synchronization signal and a vertical synchronization signal), but the exemplary embodiments of the present disclosure are not limited thereto. Here, the horizontal synchronization signal is a signal representing a time taken to display one horizontal line of a screen and the vertical synchronization signal is a signal representing a time taken to display a screen of one frame. The input data enable signal may correspond to a signal indicating a period for which a data voltage is supplied to the pixel. The control signals may be received through the pad portion PAD. For example, link lines LL for transmitting signals may be disposed in the non-display region NA. For example, driving components such as the flexible circuit board CB and the printed circuit board 160 may be connected to the pad portion PAD.

According to the present disclosure, the non-display region NA may include a first non-display region NA1, a bending region BA, and a second non-display region NA2. For example, the first non-display region NA1 may be a region surrounding at least a portion of the display region AA. The bending region BA may be a region extending from at least one side of a plurality of sides of the first non-display region NA1 and may be a bendable region. The second non-display region NA2 may be a region extending from the bending region BA, and the pad portion PAD may be disposed in the second non-display region NA2. For example, the bending region BA may be in a bent state, and the remaining region of the substrate 110 excluding the bending region BA may be in a flat state. In this case, as the bending region BA is bent, the second non-display region NA2 may be located on a rear surface of the display region AA. However, the exemplary embodiments of the present disclosure are not limited thereto.

The display region AA of the substrate 110 or the display device 1000 may be configured in various shapes depending on the design of the display device 1000. For example, the display region AA may be configured in a rectangular shape whose four corners are formed in a round shape, but the exemplary embodiments of the present disclosure are not limited thereto. In another example, the display region AA may be configured in a rectangular shape whose four corners are formed in a right-angled shape, a circular shape, or the like, but the exemplary embodiments of the present disclosure are not limited thereto.

According to the present disclosure, a width of the second non-display region NA2 where a plurality of pad electrodes PE are disposed may be wider than a width of the bending region BA where only a plurality of link lines LL are disposed. Further, a width of the display region AA where the plurality of subpixels are disposed may be wider than the width of the bending region BA where only the plurality of link lines LL are disposed. The drawings show that the width of the bending region BA is narrower than widths of other regions of the substrate 110, but a shape of the substrate 110 including the bending region BA is exemplary, and the exemplary embodiments of the present disclosure are not limited thereto.

Referring to FIG. 2, in the display device according to the exemplary embodiment of the present disclosure, the display region AA where the plurality of pixels PX are disposed and the first non-display region NA1 surrounding the display region AA may be disposed.

Referring to FIG. 3, a plurality of pixel driving circuits PD may be disposed in the display region AA. The plurality of pixel driving circuits PD may be circuits for driving the light-emitting elements of the plurality of subpixels. Each of the plurality of pixel driving circuits PD includes a plurality of transistors including a driving transistor, a storage capacitor, and the like and may control the light-emitting operations of the plurality of light-emitting elements by supplying control signals, power, and driving currents to the light-emitting elements of the plurality of subpixels. For example, the pixel driving circuit PD may include a power line and a signal line for controlling the emission on/off and/or emission time of the light-emitting elements. For example, the plurality of pixel driving circuits PD may be driving drivers manufactured using a metal-oxide-silicon field effect transistor (MOSFET) manufacturing process on a semiconductor substrate, but the exemplary embodiments of the present disclosure are not limited thereto. The driving driver may include the plurality of pixel driving circuits PD and may drive the plurality of subpixels.

For example, the pixel driving circuits PD of each of the plurality of subpixels may include a capacitor, at least one thin film transistor, and a light emitting element, such as an OLED. For example, the at least one thin film transistor may include a driving transistor, a first switching transistor, and a second switching transistor. In addition, the light emitting element may include a first electrode/a second electrode (or anode electrode, pixel electrode), an inorganic light emitting layer (or organic light emitting layer), and a second electrode/a first electrode (or cathode electrode, common electrode). However, the pixel driving circuits PD of each of the plurality of subpixels are not limited thereto, each of the plurality of subpixels may further include a compensation circuit. In this case, each of the plurality of subpixels may have various structures such as 4T2C, 5T2C, 6TIC, 6T2C, 7TIC, 7T2C, and the like.

The transistors including driving transistors and switching transistors may be implemented as a thin film transistor (TFT).

Active layers of the thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Referring together to FIG. 1, the flexible circuit board CB and the printed circuit board 160 may be disposed under the display panel 100. The flexible circuit board CB and the printed circuit board 160 may be disposed on at least an edge of one side of the display panel 100, but the exemplary embodiments of the present disclosure are not limited thereto. One side of the flexible circuit board CB may be attached to the display panel 100 and the other side may be attached to the printed circuit board 160, but the exemplary embodiments of the present disclosure are not limited thereto. The flexible circuit board CB may be a flexible film, but the exemplary embodiments of the present disclosure are not limited thereto.

The pad portion PAD including a plurality of pad electrodes PE may be disposed in the second non-display region NA2. Driving components including one or more flexible circuit boards (or flexible films) CB and the printed circuit board 160 may be attached or bonded to the pad portion PAD. The plurality of pad electrodes PE of the pad portion PAD are electrically connected to one or more flexible circuit boards (or flexible films) CB, and various signals (or power) from the printed circuit board 160 and the flexible circuit boards (or flexible films) CB may be transmitted to the plurality of pixel driving circuits PD of the display region AA.

The flexible circuit board (or flexible film) CB may be a film in which various components are disposed on a flexible base film. For example, a driving integrated circuit (IC) such as a gate driver IC or a data driver IC may be disposed on the flexible circuit board (or flexible film) CB, but the exemplary embodiments of the present disclosure are not limited thereto. The driving IC may be a component which processes data and a driving signal for displaying an image. The driving IC may be disposed in a manner such as a chip on glass (COG), a chip on film (COF), a tape carrier package (TCP), or the like depending on a mounting method, but the exemplary embodiments of the present disclosure are not limited thereto. The flexible circuit board (or flexible film) CB may be attached or bonded to the plurality of pad electrodes PE through a conductive adhesive layer, but the exemplary embodiments of the present disclosure are not limited thereto.

The printed circuit board 160 may be a component which is electrically connected to one or more flexible circuit boards (or flexible films) CB and supplies a signal to the driving IC. The printed circuit board 160 may be disposed on one side of the flexible circuit board (or flexible film) CB and may be electrically connected to the flexible circuit board (or flexible film) CB. Various components for supplying various signals to the driving IC may be disposed on the printed circuit board 160. For example, various components such as a timing controller, a power supply, a memory, a processor, and the like may be disposed on the printed circuit board 160. For example, the printed circuit board 160 may include a power management integrated circuit (PMIC), but the exemplary embodiments of the present disclosure are not limited thereto.

The printed circuit board 160 may include at least one hole 180, but the exemplary embodiments of the present disclosure are not limited thereto. An internal component which detects ambient light, temperature, or the like which may be provided to a plurality of sensors may be disposed in a region corresponding to the at least one hole 180. For example, the internal component may include an ambient light sensor (ALS) or a temperature sensor, but the exemplary embodiments of the present disclosure are not limited thereto. For example, the hole 180 may be a through hole or the like, but the exemplary embodiments of the present disclosure are not limited thereto.

Referring to FIG. 1, the polarization layer 293 may be disposed on the display panel 100. The polarization layer 293 may prevent or reduce the light generated from an external light source from entering the display panel 100 and affecting the light-emitting element or the like.

The cover member 120 may be disposed on the polarization layer 293. The cover member 120 may be a member for protecting the display panel 100. The adhesive layer 295 may be disposed between the polarization layer 293 and the cover member 123. The cover member 120 may be attached to the display panel 100 by the adhesive layer 295. The adhesive layer 295 may include an optically clear adhesive (OCA), an optically clear resin (OCR), a pressure sensitive adhesive (PSA), or the like, but the exemplary embodiments of the present disclosure are not limited thereto.

The support substrate 110 may be disposed between the display panel 100 and the printed circuit board 160. The support substrate 110 may reinforce the rigidity of the display panel 100. The support substrate 110 may be a back plate, but the exemplary embodiments of the present disclosure are not limited thereto.

Referring to FIGS. 1 to 4, a plurality of link lines LL may be disposed in the first and second non-display regions NA1 and NA2. The plurality of link lines LL may be lines which transmit various signals from one or more flexible circuit boards (or flexible films) CB and the printed circuit board 160 to the display region AA. The plurality of link lines LL may extend from the plurality of pad electrodes PE of the second non-display region NA2 toward the bending region BA and the first non-display region NA1 and may be electrically connected to a plurality of driving lines VL of the display region AA. The plurality of pixel driving circuits PD may be driven by receiving signals from one or more flexible circuit boards (or flexible films) CB and the printed circuit board 160 through the driving lines VL of the display region AA and the link lines LL of the non-display region NA.

For example, the plurality of driving lines VL may be lines for transmitting the signals output from the flexible circuit boards (or flexible films) CB and the printed circuit board 160 to the plurality of pixel driving circuits PD along with the plurality of link lines LL. The plurality of driving lines VL may be disposed in the display region AA and may be electrically connected to each of the plurality of pixel driving circuits PD. The plurality of driving lines VL may extend from the display region AA toward the non-display region NA and may be electrically connected to the plurality of link lines LL. Accordingly, the signals output from the flexible circuit boards (or flexible films) CB and the printed circuit board 160 may be respectively transmitted to the plurality of pixel driving circuits PD through the plurality of link lines LL and the plurality of driving lines VL.

As the bending region BA is bent, portions of the plurality of link lines LL may also be bent along with the bending region BA. Stress may be concentrated on portions of the bent link lines LL, and accordingly, cracks may occur in the link lines LL. Accordingly, the plurality of link lines LL may be composed of a conductive material having excellent flexibility to reduce cracks when the bending region BA is bent. For example, the plurality of link lines LL may be composed of a conductive material having excellent flexibility such as gold (Au), silver (Ag), aluminum (Al), or the like, but the exemplary embodiments of the present disclosure are not limited thereto.

Further, the plurality of link lines LL may be composed of one of various conductive materials used in the display region AA. For example, the plurality of link lines LL may be composed of molybdenum (Mo), chromium (Cr), titanium (Ti), nickel (Ni), neodymium (Nd), copper (Cu), and an alloy of silver (Ag) and magnesium (Mg), or an alloy thereof, but the exemplary embodiments of the present disclosure are not limited thereto. The plurality of link lines LL may be formed in a multi-layer structure including various conductive materials.

For example, the plurality of link lines LL may be configured in a triple-layer structure of titanium (Ti)/aluminum (Al)/titanium (Ti), but the exemplary embodiments of the present disclosure are not limited thereto.

The plurality of link lines LL may be configured in various shapes to reduce stress.

At least portions of the plurality of link lines LL disposed on the bending region BA may extend in the same direction as an extending direction of the bending region BA or may extend in a different direction from the extending direction of the bending region BA to reduce stress. For example, when the bending region BA extends in one direction from the first non-display region NA1 toward the second non-display region NA2, at least portions of the link lines LL disposed on the bending region BA may extend in a direction oblique to the one direction.

In another example, at least portions of the plurality of link lines LL may be configured in various pattern shapes. For example, at least portions of the plurality of link lines LL disposed on the bending region BA may have a shape in which a conductive pattern having at least one of a diamond shape, a rhombus shape, a trapezoidal wave shape, a triangular wave shape, a sawtooth wave shape, a sine wave shape, a circular shape, and an omega (Ω) shape is repeatedly disposed, but the exemplary embodiments of the present disclosure are not limited thereto.

Accordingly, in order to minimize or reduce the stress concentrated on the plurality of link lines LL and cracks resulting from the stress, the plurality of link lines LL may be formed in various shapes including the above-described shapes, but the exemplary embodiments of the present disclosure are not limited thereto.

FIG. 4 is a view showing a circuit structure according to an exemplary embodiment of the present disclosure.

In FIG. 4, an example in which one light-emitting element ED is connected to a micro driver μDriver is shown, but the present disclosure is not limited thereto. For example, 8 light-emitting elements ED may be connected to one micro driver μDriver. In another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element (μLED).

One micro driver μDriver may include a driving transistor T_{DR} and a light-emitting transistor T_{EM}, but exemplary embodiments herein are not limited thereto.

For example, in the driving transistor T_{DR}, a high potential power voltage VDD may be applied to a first electrode, a first electrode of the light-emitting transistor T_{EM} may be connected to a second electrode, and a scan signal SC may be applied to a gate electrode. The scan signal SC applied to the gate electrode of the driving transistor T_{DR} is a direct current power source, and a fixed reference voltage Vref may be applied for each frame, but the exemplary embodiments of the present disclosure are not limited thereto.

In the light-emitting transistor T_{EM}, the second electrode of the driving transistor T_{DR} may be connected to the first electrode, the light-emitting element ED may be connected to a second electrode, and an emission signal EM may be applied to a gate electrode. The emission signal EM applied to the gate electrode of the light-emitting transistor T_{EM} may be a pulse width modulation signal which varies for each frame, but the exemplary embodiments of the present disclosure are not limited thereto.

A first electrode of the light-emitting element ED may be connected to the second electrode of the light-emitting transistor T_{EM}, and a second electrode of the light-emitting element ED may be connected to the ground. For example, the first electrode of the light-emitting element ED may be an anode electrode and the second electrode of the light-emitting element ED may be a cathode electrode, but the exemplary embodiments of the present disclosure are not limited thereto.

The driving transistor T_{DR} and the light-emitting transistor T_{EM} may each be an n-type transistor or a p-type transistor.

In the micro driver μDriver, the driving transistor T_{DR} may be turned on by the scan signal SC applied from a timing controller T-CON, and the light-emitting transistor T_{EM} may be turned on by the emission signal EM. Accordingly, as a driving current is applied to the light-emitting element ED via the driving transistor T_{DR} and the light-emitting transistor T_{EM} by a high potential power voltage VDD applied to the first electrode of the driving transistor T_{DR}, the light-emitting element ED may emit light.

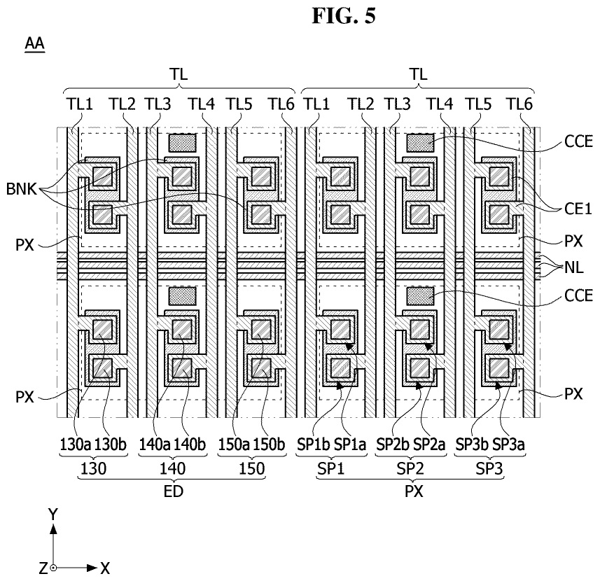

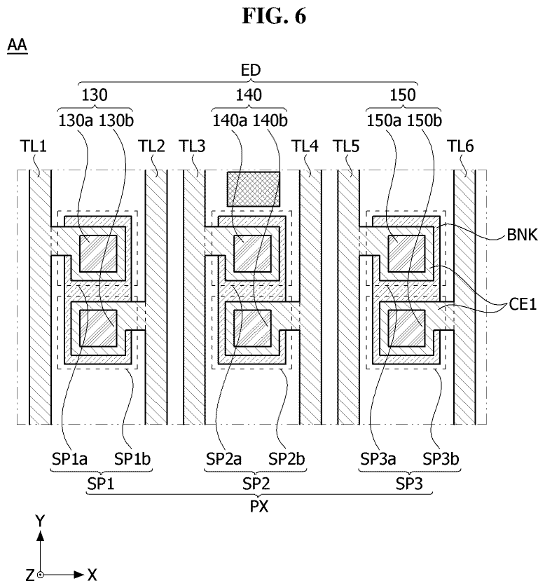

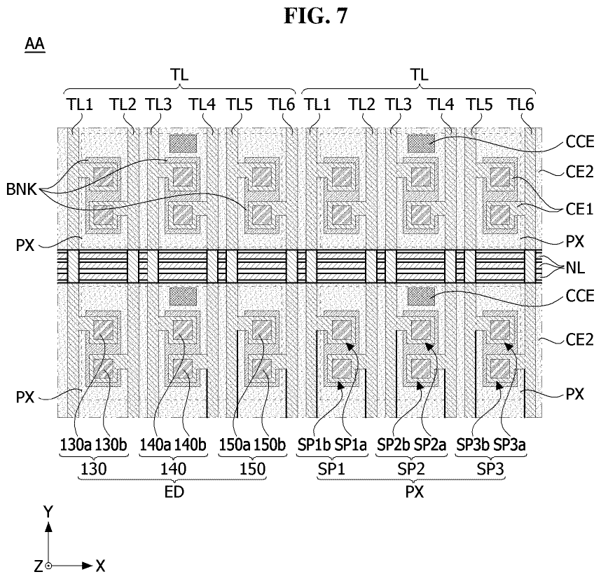

FIG. 5 is a plan view of the display device according to an exemplary embodiment of the present disclosure. FIG. 6 is a plan view of the display device according to an exemplary embodiment of the present disclosure. FIG. 7 is a plan view of the display device according to an exemplary embodiment of the present disclosure.

In FIGS. 5 and 6, a plurality of signal lines TL, a plurality of communication lines NL, a plurality of first electrodes CE1, a plurality of banks BNK, and a plurality of light-emitting elements ED are shown, but the exemplary embodiments of the present disclosure are not limited thereto. FIG. 7 is an enlarged plan view in which a plurality of second electrodes CE2 are additionally disposed in FIG. 5.

Referring to FIGS. 5 and 6, a plurality of pixels PX, each composed of a plurality of subpixels may be disposed in the display region AA. Each of the plurality of subpixels includes a light-emitting element ED and may independently emit light. The plurality of subpixels may be disposed in a matrix form, forming a plurality of rows and a plurality of columns, but the exemplary embodiments of the present disclosure are not limited thereto.

The plurality of subpixels may include a first subpixel SP1, a second subpixel SP2, and a third subpixel SP3. For example, one of the first subpixel SP1, the second subpixel SP2, and the third subpixel SP3 may be a red subpixel, another may be a green subpixel, and the remaining one may be a blue subpixel. The types of the plurality of subpixels are exemplary, and the exemplary embodiments of the present disclosure are not limited thereto.

Each of the plurality of pixels PX may include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may be composed of a 1-1 subpixel SP1a and a 1-2 subpixel SP1b. The pair of second subpixels SP2 may be composed of a 2-1 subpixel SP2a and a 2-2 subpixel SP2b.

The pair of third subpixels SP3 may be composed of a 3-1 subpixel SP3a and a 3-2 subpixel SP3b. For example, one pixel PX may include the 1-1 subpixel SP1a and the 1-2 subpixel SP1b, the 2-1 subpixel SP2a and the 2-2 subpixel SP2b, and the 3-1 subpixel SP3a and the 3-2 subpixel SP3b, but the exemplary embodiments of the present disclosure are not limited thereto.

The plurality of subpixels forming one pixel PX may be arranged in various ways. For example, in one pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. Alternatively, in one pixel PX, the pair of first subpixels SP1 may be disposed in the same row, the pair of second subpixels SP2 may be disposed in the same row, and the pair of third subpixels SP3 may be disposed in the same row. The first subpixel SP1, the second subpixel SP2, and the third subpixel SP3 may be disposed in the same column. The number and arrangement of the plurality of subpixels forming one pixel PX are exemplary, and the exemplary embodiments of the present disclosure are not limited thereto.

The plurality of signal lines TL may be disposed in regions between the plurality of subpixels. The plurality of signal lines TL may extend between the plurality of subpixels in a column direction. The plurality of signal lines TL may be lines which transmit an anode voltage from the pixel driving circuit PD to the plurality of subpixels. For example, the plurality of signal lines TL may be electrically connected to the plurality of pixel driving circuits PD and the first electrodes CE1 of the plurality of subpixels.

The anode voltage output from the pixel driving circuit PD may be transmitted to the first electrodes CE1 of the plurality of subpixels through the plurality of signal lines TL. For example, the first electrode CE1 may be an electrode electrically connected to an anode electrode 134 of the light-emitting element ED. Accordingly, the anode voltage from the signal line TL may be transmitted to the anode electrode 134 of the light-emitting element ED through the first electrode CE1.

Accordingly, instead of forming a plurality of transistors and a plurality of storage capacitors in each of the plurality of subpixels, a structure of the display device 1000 may be simplified using a pixel driving circuit PD in which a plurality of pixel circuits are integrated. Further, as the circuits disposed in each of the plurality of subpixels are integrated into one pixel driving circuit PD, high efficiency and low power driving may be possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first subpixels SP1, respectively. The third signal line TL3 and the fourth signal line TL4 may be electrically connected to the pair of second subpixels SP2, respectively. The fifth signal line TL5 and the sixth signal line TL6 may be electrically connected to the pair of third subpixels SP3, respectively.

The first signal line TL1 may be disposed on one side of the pair of first subpixels SP1, and the second signal line TL2 may be disposed on another side of the pair of first subpixels SP1. The first signal line TL1 may be electrically connected to the first electrode CE1 of one of the pair of first subpixels SP1, for example, the 1-1 subpixel SP1a. The second signal line TL2 may be electrically connected to the first electrode CE1 of the other of the pair of first subpixels SP1, for example, the 1-2 subpixel SP1b.

The third signal line TL3 may be disposed on one side of the pair of second subpixels SP2, and the fourth signal line TL4 may be disposed on another side of the pair of second subpixels SP2. For example, the third signal line TL3 may be disposed adjacent to the second signal line TL2. The third signal line TL3 may be electrically connected to the first electrode CE1 of one of the pair of second subpixels SP2, for example, the 2-1 subpixel SP2a. The fourth signal line TL4 may be electrically connected to the first electrode CE1 of the other of the pair of second subpixels SP2, for example, the 2-2 subpixel SP2b.

The fifth signal line TL5 may be disposed on one side of the pair of third subpixels SP3, and the sixth signal line TL6 may be disposed on another side of the pair of third subpixels SP3. For example, the fifth signal line TL5 may be disposed adjacent to the fourth signal line TL4. The sixth signal line TL6 may be disposed adjacent to the first signal line TL1 connected to the neighboring pixel PX. The fifth signal line TL5 may be electrically connected to the first electrode CE1 of one of the pair of third subpixels SP3, for example, the 3-1 subpixel SP3a. The sixth signal line TL6 may be electrically connected to the first electrode CE1 of the other of the pair of third subpixels SP3, for example, the 3-2 subpixel SP3b.

As shown in FIG. 5, a first pixel includes a pair of first sub-pixels SP1, a pair of second sub-pixels SP2, and a pair of third sub-pixels SP3, wherein, the pair of first sub-pixels SP1 includes a 1-1 sub-pixel SP1a and a 1-2 sub-pixel SP1b, the pair of second sub-pixels SP2 includes a 2-1 sub-pixel SP2a and a 2-2 sub-pixel SP2b, and the pair of third sub-pixels SP3 includes a 3-1 sub-pixel SP3a and a 3-2 sub-pixel SP3b. The first signal line TL1 may be electrically connected to the first electrode CE1 of the 1-1 sub-pixel SP1a, the second signal line TL2 may be electrically connected to the first electrode CE1 of the 1-2 sub-pixel SP1b, the third signal line TL3 may be electrically connected to the first electrode CE1 of the 2-1 sub-pixel SP2a, the fourth signal line TL4 may be electrically connected to the first electrode CE1 of the 2-2 sub-pixel SP2b, the fifth signal line TL5 may be electrically connected to the first electrode CE1 of the 3-1 sub-pixel SP3a, and the sixth signal line TL6 may be electrically connected to the first electrode CE1 of the 3-2 sub-pixel SP3b. Meanwhile, the first signal line TLI connected to the first pixel is adjacent to the sixth signal line TL6 connected to a second pixel adjacent to the first pixel. However, the present disclosure is not limited thereto.

The plurality of signal lines TL may be formed of a conductive material. For example, the plurality of signal lines TL may be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the exemplary embodiments of the present disclosure are not limited thereto. In another example, the plurality of signal lines TL may be formed in a multi-layer structure of conductive materials. For example, the plurality of signal lines TL may be formed in a multi-layer structure of titanium (Ti)/aluminum (Al)/titanium (Ti)/indium tin oxide (ITO), but the exemplary embodiments of the present disclosure are not limited thereto.

The plurality of communication lines NL may be disposed in regions between the plurality of pixels PX. The plurality of communication lines NL may be disposed to extend in a row direction in the regions between the plurality of pixels PX. The plurality of communication lines NL may be disposed in regions between the plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, and the like, but the exemplary embodiments of the present disclosure are not limited thereto.

According to the present disclosure, a bank BNK may be disposed in each of the plurality of subpixels. The plurality of banks BNK may be structures on which the plurality of light-emitting elements ED are seated. The plurality of banks BNK may guide the positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNK may be bank patterns or structures, or the like, but the exemplary embodiments of the present disclosure are not limited thereto.

A bank BNK of the first subpixel SP1, a bank BNK of the second subpixel SP2, and a bank BNK of the third subpixel SP3 may disposed spaced apart from each other. The bank BNK of the first subpixel SP1, the bank BNK of the second subpixel SP2, and the bank BNK of the third subpixel SP3 may be configured to be separated. Accordingly, the banks BNK of the first subpixel SP1, the second subpixel SP2, and the third subpixel SP3 to which different types of light-emitting elements ED are transferred may be easily identified.

A bank BNK of the 1-1 subpixel SP1a and a bank BNK of the 1-2 subpixel SP1b may be connected to each other or may be formed to be spaced apart or separated from each other. For example, in consideration of the design of the transfer process requirements or the like, the bank BNK of the 1-1 subpixel SP1a and the bank BNK of the 1-2 subpixel SP1b where the same type of light-emitting elements ED are disposed may be connected to each other or may be spaced apart or separated from each other. Further, a bank BNK of the 2-1 subpixel SP2a and a bank BNK of the 2-2 subpixel SP2b may be connected to each other or may be formed to be spaced apart or separated from each other. A bank BNK of the 3-1 subpixel SP3a and a bank BNK of the 3-2 subpixel SP3b may be connected to each other or may be formed to be spaced apart or separated from each other. Accordingly, the banks of the pair of first subpixels SP1, the banks BNK of the pair of second subpixels SP2, and the banks BNK of the pair of third subpixels SP3 may be formed in various ways, and the exemplary embodiments of the present disclosure are not limited thereto.

The plurality of banks BNK may be formed of an opaque material (for example, black) in order to prevent or at least reduce light interference between adjacent pixels. In this case, the bank BNK may include a light shielding material constituted by at least one of a color pigment, organic black, or carbon, without being limited thereto.

For example, the plurality of banks BNK may be formed of an organic insulating material. The plurality of banks BNK may be composed of a single layer or multiple layers of an organic insulating material. For example, the plurality of banks BNK may be composed of a photoresist, a polyimide (PI)-based material, an acryl-based material, or the like, but the exemplary embodiments of the present disclosure are not limited thereto.

Meanwhile, the plurality of banks BNK may include an inorganic insulating material, such as silicon nitride (SiNx) or silicon oxide (SiOx), or the bank BNK may be formed of black resin. However, the present disclosure is not limited thereto.

The first electrode CE1 may be disposed in each of the plurality of subpixels. The first electrode CE1 may be disposed on the bank BNK. The first electrode CE1 may be electrically connected to one of the plurality of signal lines TL. At least a portion of the first electrode CE1 may extend outside the bank BNK and may be electrically connected to the signal line TL most adjacent to the first electrode CE1. For example, a portion of the first electrode CEI of the 1-1 subpixel SP1a may extend to one side region of the 1-1 subpixel SP1a and may be electrically connected to the first signal line TL1, and a portion of the first electrode CE1 of the 1-2 subpixel SP1b may extend to the other side region of the 1-2 subpixel SP1b and may be electrically connected to the second signal line TL2. A portion of the first electrode CE1 of the 2-1 subpixel SP2a may extend to one side region of the 2-1 subpixel SP2a and may be electrically connected to the third signal line TL3, and a portion of the first electrode CE1 of the 2-2 subpixel SP2b may extend to the other side region of the 2-2 subpixel SP2b and may be electrically connected to the fourth signal line TL4. A portion of the first electrode CE1 of the 3-1 subpixel SP3a may extend to one side region of the 3-1 subpixel SP3a and may be electrically connected to the fifth signal line TL5, and a portion of the first electrode CE1 of the 3-2 subpixel SP3b may extend to the other side region of the 3-2 subpixel SP3b and may be electrically connected to the sixth signal line TL6.

The first electrode CE1 may be electrically connected to the anode electrode 134 of the light-emitting element ED and may transmit the anode voltage from the pixel driving circuit PD to the light-emitting element ED through the signal line TL. Different voltages may be applied to the first electrode CE1 of each of the plurality of subpixels depending on the image to be displayed. For example, different voltages may be applied to the first electrode CE1 of each of the plurality of subpixels. Accordingly, the first electrode CE1 may be a pixel electrode, but the exemplary embodiments of the present disclosure are not limited thereto.

The first electrode CE1 may be composed of a conductive material. For example, the first electrode CE1 may be integrally configured with the plurality of signal lines TL. For example, the first electrode CE1 may be composed of the same conductive material as the plurality of signal lines TL, but the exemplary embodiments of the present disclosure are not limited thereto. For example, the first electrode CE1 may be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the exemplary embodiments of the present disclosure are not limited thereto. In another example, the first electrode CE1 may be formed in a multi-layer structure of conductive materials. For example, the plurality of first electrodes CE1 may be formed in a multi-layer structure of titanium (Ti)/aluminum (Al)/titanium (Ti)/indium tin oxide (ITO), but the exemplary embodiments of the present disclosure are not limited thereto.

The light-emitting element ED may be disposed in each of the plurality of subpixels. The plurality of light-emitting elements ED may be any one of an LED and a micro LED, but the exemplary embodiments of the present disclosure are not limited thereto. The plurality of light-emitting elements ED may be disposed on the banks BNK and the first electrodes CE1. The plurality of light-emitting elements ED may be disposed on the first electrodes CE1 and may be electrically connected to the first electrodes CE1. Accordingly, the light-emitting element ED may emit light by receiving the anode voltage from the pixel driving circuit PD through the signal line TL and the first electrode CE1.

The plurality of light-emitting elements ED may include a first light-emitting element 130, a second light-emitting element 140, and a third light-emitting element 150. The first light-emitting element 130 may be disposed in the first subpixel SP1. The second light-emitting element 140 may be disposed in the second subpixel SP2. The third light-emitting element 150 may be disposed in the third subpixel SP3. For example, one of the first light-emitting element 130, the second light-emitting element 140, and the third light-emitting element 150 may be a red light-emitting element, another may be a green light-emitting element, and the remaining one may be a blue light-emitting element, for example, the first light-emitting element 130 is a red light-emitting element, the second light-emitting element 140 is a green light-emitting element, and the third light-emitting element 150 is a blue light-emitting element, but the exemplary embodiments of the present disclosure are not limited thereto. Accordingly, various colors of light including white may be implemented by combining red light, green light, and blue light emitted from the plurality of light-emitting elements ED. The types of the plurality of light-emitting elements ED are exemplary, and the exemplary embodiments of the present disclosure are not limited thereto.

The first light-emitting element 130 may include a 1-1 light-emitting element 130a disposed in the 1-1 subpixel SP1a and a 1-2 light-emitting element 130b disposed in the 1-2 subpixel SP1b. The second light-emitting element 140 may include a 2-1 light-emitting element 140a disposed in the 2-1 subpixel SP2a and a 2-2 light-emitting element 140b disposed in the 2-2 subpixel SP2b. The third light-emitting element 150 may include a 3-1 light-emitting element 150a disposed in the 3-1 subpixel SP3a and a 3-2 light-emitting element 150b disposed in the 3-2 subpixel SP3b.

Referring together to FIGS. 5, 6, and 7, a second electrode CE2 may be disposed in each of the plurality of subpixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to a cathode electrode 135 of the light-emitting element ED to transmit a cathode voltage from the pixel driving circuit PD to the light-emitting element ED. The same cathode voltage may be applied to the second electrode CE2 of each of the plurality of subpixels. For example, the same voltage may be applied to the second electrode CE2 of each of the plurality of subpixels and the cathode electrode 135 of the light-emitting element ED. Accordingly, the second electrode CE2 may be a common electrode, but the exemplary embodiments of the present disclosure are not limited thereto.

At least some of the plurality of subpixels may share the second electrode CE2. At least some of the second electrodes CE2 of each of the plurality of subpixels may be electrically connected to each other. As the same voltage is applied to the second electrodes CE2, the second electrodes CE2 of at least some of the subpixels may be shared and used. For example, the second electrodes CE2 of at least some pixels PX of the plurality of pixels PX disposed in the same row may be connected to each other. For example, one second electrode CE2 may be disposed in the plurality of pixels PX. One second electrode CE2 may be disposed for every n subpixels.

For example, some of the second electrodes CE2 of each of the plurality of subpixels may be disposed to be spaced apart or separated from each other. For example, the second electrode CE2 connected to pixels PX in an nth row and the second electrode CE2 connected to pixels PX in an n+1^{th} row may be disposed to be spaced apart or separated from each other. For example, the plurality of second electrodes CE2 may be disposed spaced apart from each other with the plurality of communication lines NL extending in the row direction therebetween. Accordingly, the number of subpixels may be greater than the number second electrodes CE2. In another example, all the second electrodes CE2 of the plurality of subpixels may be connected to each other and thus only one second electrode CE2 may be disposed on the substrate 110, but the exemplary embodiments of the present disclosure are not limited thereto.

The plurality of second electrodes CE2 may be composed of a transparent conductive material, but the exemplary embodiments of the present disclosure are not limited thereto. The plurality of second electrodes CE2 may be formed of a transparent conductive material so that light emitted from the light-emitting element ED may be directed toward an upper portion of the second electrodes CE2. For example, the second electrode CE2 may be composed of a transparent conductive material such as indium tin oxide (ITO), indium zinc oxide (IZO), indium gallium zinc oxide (IGZO), or the like, but the exemplary embodiments of the present disclosure are not limited thereto.

The plurality of contact electrodes CCE may be disposed on the substrate 110. For example, the plurality of contact electrodes CCE may be disposed spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, when micro LEDs are used as the light-emitting elements ED, the display device 1000 may be manufactured by forming a plurality of micro LEDs on a wafer and transferring the micro LEDs to the substrate 110 of the display device 1000. In the process of transferring the plurality of light-emitting elements ED having a fine size from the wafer to the substrate 110, various defects may occur. For example, in some subpixels, a non-transfer defect in which the light-emitting element ED is not transferred may occur, and in other subpixels, a defect in which the light-emitting element ED is transferred to an incorrect position due to an alignment error may occur. Further, although the transfer process is normally performed, the transferred light-emitting element ED itself may be defective. Accordingly, in consideration of defects during the transfer process of the plurality of light-emitting elements ED, the plurality of light-emitting elements ED of the same type may be transferred to one subpixel. A lighting test may be performed on the plurality of light-emitting elements ED, and ultimately, only one light-emitting element ED that is determined to be normal may be used.

For example, the 1-1 light-emitting element 130a and the 1-2 light-emitting element 130b may be transferred together to one pixel PX and inspected for defects. When both the 1-1 light-emitting element 130a and the 1-2 light-emitting element 130b are determined to be normal, the 1-1 light-emitting element 130a may be used and the 1-2 light-emitting element 130b may not be used. In another example, when the 1-2 light-emitting element 130b is determined to be normal among the 1-1 light-emitting element 130a and the 1-2 light-emitting element 130b, the 1-1 light-emitting element 130a may not be used and the 1-2 light-emitting element 130b may be used. Accordingly, even when the plurality of light-emitting elements ED of the same type are transferred to one pixel PX, ultimately, one light-emitting element ED may be used.

Accordingly, one of the pair of light-emitting elements ED may be a main (or primary) light-emitting element ED and the other may be a redundancy light-emitting element ED. The redundancy light-emitting element ED may be a spare light-emitting element ED transferred to prepare for a defect of the main light-emitting element ED. When the main light-emitting element ED is defective, the redundancy light-emitting element ED may be used as a replacement. Accordingly, the deterioration of display quality due to the defects of the main light-emitting element ED and the redundancy light-emitting element ED may be minimized by transferring the main light-emitting element ED and the redundancy light-emitting element ED together to one pixel PX. In addition, the main light-emitting element ED and the redundancy light-emitting element ED are different in name, structures and functions thereof may be totally same, for example, the main light-emitting element ED may also be called the redundancy light-emitting element ED, and the redundancy light-emitting element ED may also be called the main light-emitting element ED, but not limited thereto.

For example, the 1-1 light-emitting element 130a, the 2-1 light-emitting element 140a, and the 3-1 light-emitting element 150a transferred to one pixel PX may be used as the main light-emitting elements ED, and the 1-2 light-emitting element 130b, the 2-2 light-emitting element 140b, and the 3-2 light-emitting element 150b may be used as the redundancy light-emitting elements ED.

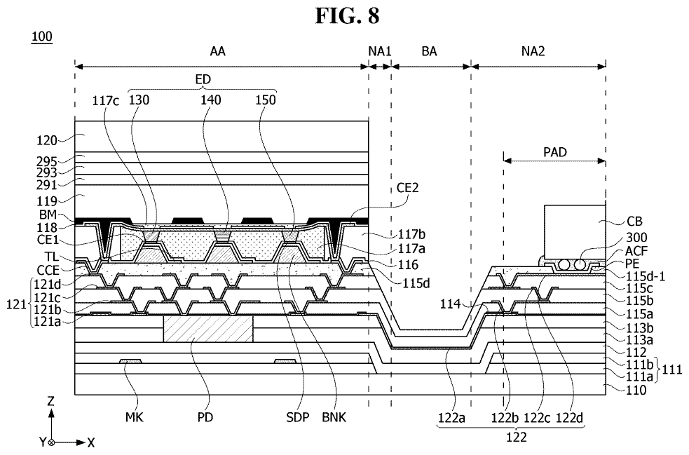

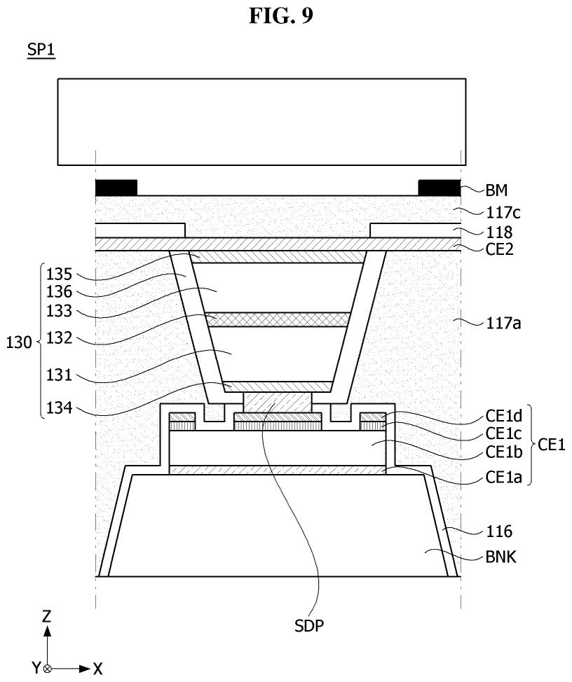

FIG. 8 is a cross-sectional view of a display device taken along line I-I′ in FIG. 2 according to an exemplary embodiment of the present disclosure. FIG. 9 is an enlarged cross-sectionalview of the display device according to an exemplary embodiment of the present disclosure. For example, FIG. 8 is a cross-sectional view of the display region AA, the first and second non-display regions NA1 and NA2, and the bending region BA.

Referring to FIG. 8, a buffer layer 111 may be disposed on the remaining region of the substrate 110 excluding the bending region BA. The buffer layer 111 may include a first buffer layer 111a and a second buffer layer 111b.

The first buffer layer 111a and the second buffer layer 111b may be disposed in the display region AA, the first non-display region NA1, and the second non-display region NA2. The first buffer layer 111a and the second buffer layer 111b may reduce the penetration of moisture or impurities through the substrate 110. The first buffer layer 111a and the second buffer layer 111b may be formed of an inorganic insulating material. For example, the first buffer layer 111a and the second buffer layer 111b may be composed of a single layer or multiple layers of silicon oxide (SiOx) or silicon nitride (SiNx). For example, the first buffer layer 111a and the second buffer layer 111b may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto. The first buffer layer 111a and the second buffer layer 111b may be excluded in accordance with the structure or properties of the display device. However, the exemplary embodiments of the present disclosure are not limited thereto.

The non-display region NA may include the first non-display region NA1, the bending region BA, and the second non-display region NA2. The first and second buffer layers 111a and 111b may be disposed in the first and second non-display regions NA1 and NA2 and may be removed in the bending region BA. For example, the buffer layer 111 may be composed of a single layer or multiple layers of silicon oxide (SiOx) or silicon nitride (SiNx) which is an inorganic film material, but the exemplary embodiments of the present disclosure are not limited thereto. For example, portions of the first buffer layer 111a and the second buffer layer 111b in the bending region BA may be removed. An upper surface of the substrate 110 located in the bending region BA may be exposed from the first buffer layer 111a and the second buffer layer 111b. Cracks in the first buffer layer 111a and the second buffer layer 111b which may occur during bending may be minimized by removing the first buffer layer 111a and the second buffer layer 111b formed of an inorganic insulating material from the bending region BA.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align the position of the pixel driving circuit PD transferred onto an adhesive layer 112. In another example, the plurality of alignment keys MK may be omitted.

The adhesive layer 112 may be disposed on the second buffer layer 111b. The adhesive layer 112 may be disposed in the display region AA, the first non-display region NA1, the bending region BA, and the second non-display region NA2. In another example, at least a portion of the adhesive layer 112 may be removed in the non-display region NA including the bending region BA. For example, the adhesive layer 112 may be formed of any one of an adhesive polymer, an epoxy resin, a UV-curable resin, a polyimide-based material, an acrylate-based material, a urethane-based material, and polydimethylsiloxane (PDMS), but the exemplary embodiments of the present disclosure are not limited thereto.

The pixel driving circuit PD may be disposed on the adhesive layer 112 in the display region AA. When the pixel driving circuit PD is implemented as a driving driver, the driving driver may be mounted on the adhesive layer 112 by a transfer process, but the exemplary embodiments of the present disclosure are not limited thereto.

A first protective layer 113a and a second protective layer 113b may be disposed on the adhesive layer 112 and the pixel driving circuit PD. The first protective layer 113a and the second protective layer 113b may be disposed to surround the sides of the pixel driving circuit PD, but the exemplary embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed in the bending region BA may be omitted. For example, the first protective layer 113a may be entirely disposed in the display region AA and the non-display region NA, and the second protective layer 113b may be partially disposed in the display region AA, the first non-display region NA1, and the second non-display region NA2. For example, a portion of the second protective layer 113b in the bending region BA may be removed. However, the exemplary embodiments of the present disclosure are not limited thereto.

The first protective layer 113a and the second protective layer 113b may be composed of an organic insulating material, but the exemplary embodiments of the present disclosure are not limited thereto. For example, the first protective layer 113a and the second protective layer 113b may be composed of a photoresist, a polyimide (PI)-based material, a photo acrylic-based material, or the like, but the exemplary embodiments of the present disclosure are not limited thereto. For example, the first protective layer 113a and the second protective layer 113b may be overcoating layers or insulating layers, but the exemplary embodiments of the present disclosure are not limited thereto.

A plurality of first connection lines 121 may be disposed on the second protective layer 113b in the display region AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the exemplary embodiments of the present disclosure are not limited thereto.

For example, a plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CE1 or the second electrode CE2.

For example, the first and second protective layers 113a and 113b may be composed of an organic insulating material. For example, the first and second protective layers 113a and 113b may be composed of a photoresist, a polyimide (PI)-based material, a photo acrylic-based material, or the like, but the exemplary embodiments of the present disclosure are not limited thereto. For example, the first protective layer 113a and the second protective layer 113b may be composed of the same material, but the exemplary embodiments of the present disclosure are not limited thereto.

An inorganic insulating layer 114 may be composed of a single layer or multiple layers of silicon oxide (SiOx) or silicon nitride (SiNx) which is an inorganic film material, for example, the inorganic insulating layer 114 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

A first organic insulating layer 115a may be disposed on the inorganic insulating layer 114. The first organic insulating layer 115a may be composed of an organic insulating material, but the exemplary embodiments of the present disclosure are not limited thereto. For example, the first organic insulating layer 115a may be composed of a photoresist, a polyimide (PI)-based material, a photo acrylic-based material, or the like, but the exemplary embodiments of the present disclosure are not limited thereto.

Further, a plurality of 1-2 connection lines 121b may be disposed on the first organic insulating layer 115a. The plurality of 1-2 connection lines 121b may be connected to or directly connected to the pixel driving circuit PD. For example, some of the 1-2 connection lines 121b may be directly connected to the pixel driving circuit PD through contact holes of the inorganic insulating layer 114. Other 1-2 connection lines 121b may be electrically connected to the 1-1 connection line 121a through contact holes of the inorganic insulating layer 114. However, the exemplary embodiments of the present disclosure are not limited thereto. The voltage output from the pixel driving circuit PD may be transmitted to the first electrode CE1 or the second electrode CE2 through the plurality of 1-2 connection lines 121b and other connection lines.

A second organic insulating layer 115b may be disposed on the plurality of 1-2 connection lines 121b. The second organic insulating layer 115b may be entirely disposed in the display region AA and the non-display region NA, but the exemplary embodiments of the present disclosure are not limited thereto. The second organic insulating layer 115b may be composed of an organic insulating material, but the exemplary embodiments of the present disclosure are not limited thereto. For example, the second organic insulating layer 115b may be composed of a photoresist, a polyimide (PI)-based material, a photo acrylic-based material, or the like, but the exemplary embodiments of the present disclosure are not limited thereto.

A plurality of 1-3 connection lines 121c may be disposed on the second organic insulating layer 115b. The plurality of 1-3 connection lines 121c may be electrically connected to the plurality of 1-2 connection lines 121b. For example, the 1-3 connection lines 121c may be electrically connected to the 1-2 connection lines 121b through contact holes of the second organic insulating layer 115b.

A third organic insulating layer 115c may be disposed on the plurality of 1-3 connection lines 121c. The third organic insulating layer 115c may be disposed in the remaining region excluding the bending region BA, but the exemplary embodiments of the present disclosure are not limited thereto. The third organic insulating layer 115c may be disposed in the display region AA, the first non-display region NA1, and the second non-display region NA2, but the exemplary embodiments of the present disclosure are not limited thereto. For example, a portion of the third organic insulating layer 115c disposed in the bending region BA may be removed. The third organic insulating layer 115c may be composed of an organic insulating material, but the exemplary embodiments of the present disclosure are not limited thereto. For example, the third organic insulating layer 115c may be composed of a photoresist, a polyimide (PI)-based material, a photo acrylic-based material, or the like, but the exemplary embodiments of the present disclosure are not limited thereto.

A plurality of 1-4 connection lines 121d may be disposed on the third organic insulating layer 115c. The plurality of 1-4 connection lines 121d may be electrically connected to the plurality of 1-3 connection lines 121c. For example, the 1-4 connection lines 121d may be electrically connected to the 1-3 connection lines 121c through contact holes of the third organic insulating layer 115c.

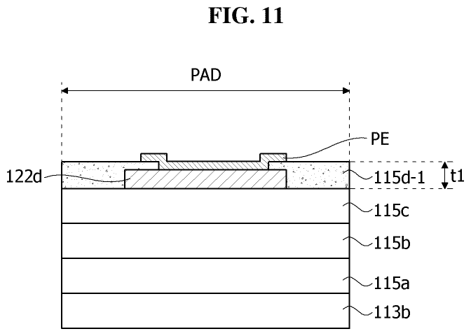

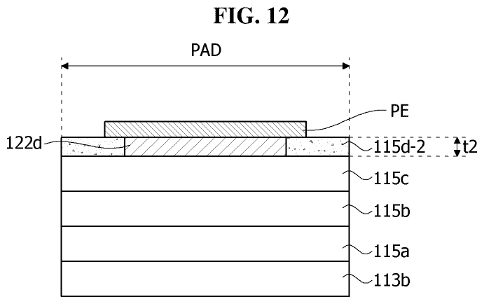

A fourth organic insulating layer 115d may be disposed on the plurality of 1-4 connection lines 121d. The fourth organic insulating layer 115d may be disposed in the remaining region excluding the bending region BA, but the exemplary embodiments of the present disclosure are not limited thereto. The fourth organic insulating layer 115d may be disposed in the display region AA, the first non-display region NA1, and the second non-display region NA2, but the exemplary embodiments of the present disclosure are not limited thereto. Here, the fourth organic insulating layer 115d may include a 4-1 organic insulating layer 115d-1 disposed in the display region AA and a 4-2 organic insulating layer 115d-2 disposed in the pad portion PAD. Since the 4-2 organic insulating layer 115d-2 is formed in the pad portion PAD, line defects, for example, damage to the side surface of the connection line under the pad electrode PE, and a residual film and corrosion of the metal layer of the pad electrode PE may be improved. Further, among the fourth organic insulating layers 115d, a second thickness (t2 in FIG. 12) of the 4-2 organic insulating layer 115d-2 may be formed to be lower than a first thickness (t1 in FIG. 11) of the 4-1 organic insulating layer 115d-1. Since a portion of the 4-2 insulation layer 115d-2 supports the side surface of the pad electrode PE, the deterioration of pressing of the conductive ball 300 applied to connect the circuit board on the pad electrode PE may be minimized. However, the present disclosure is not limited thereto.

According to the present disclosure, a plurality of second connection lines 122 may be disposed on the second protective layer 113b in the non-display region NA. The plurality of second connection lines 122 may be lines for transmitting signals transmitted from the flexible circuit board (or flexible film) CB and the printed circuit board 160 (see in FIG. 1) to the pad portion PAD to the pixel driving circuit PD of the display region AA. For example, the plurality of second connection lines 122 may be electrically connected to the plurality of pad electrodes PE to receive signals from the flexible circuit board (or flexible film) CB and the printed circuit board 160.

For example, the plurality of second connection lines 122 may extend from the pad portion PAD toward the display region AA and transmit the signals to lines in the display region AA. In this case, the plurality of second connection lines 122 may function as link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display region NA2 to the bending region BA and the first non-display region NA1. The plurality of 2-1 connection lines 122a may transmit signals transmitted from the flexible circuit board (or flexible film) CB and the printed circuit board to the pad portion PAD to the pixel driving circuit PD of the display region AA.

A plurality of 2-2 connection lines 122b may be disposed on the inorganic insulating layer 114 and the first organic insulating layer 115a. The plurality of 2-2 connection lines 122b may be disposed in the second non-display region NA2. The 2-2 connection lines 122b may be electrically connected to the 2-1 connection lines 122a through contact holes of the inorganic insulating layer 114. Accordingly, the signals from the flexible circuit board (or flexible film) CB and the printed circuit board may be transmitted to the 2-1 connection lines 122a through the 2-2 connection lines 122b.

The 2-3 connection line 122c may be disposed on the second organic insulating layer 115b. The 2-3 connection line 122c may be disposed in the second non-display region NA2. The 2-3 connection line 122c may be electrically connected to the 2-2 connection lines 122b through a contact hole of the second organic insulating layer 115b. Accordingly, the signals from the flexible circuit board (or flexible film) CB and the printed circuit board may be transmitted to the 2-1 connection lines 122a through the 2-3 connection line 122c and the 2-2 connection lines 122b.

The third organic insulating layer 115c may be disposed on the second organic insulating layer 115b and the 2-3 connection line 122c. The 2-4 connection line 122d may be disposed on the third organic insulating layer 115c. The 2-4 connection line 122d may be disposed in the second non-display region NA2. The 2-4 connection line 122d may be electrically connected to the 2-3 connection line 122c through a contact hole of the third organic insulating layer 115c. Accordingly, the signals from the flexible film FF and the printed circuit board may be transmitted to the 2-1 connection lines 122a through the 2-4 connection line 122d, the 2-3 connection line 122c, and the 2-2 connection lines 122b.

The plurality of first connection lines 121 and the plurality of second connection lines 122 may be formed of a conductive material having excellent flexibility or any one of various conductive materials used in the display region AA. For example, the second connection line 122 partially disposed in the bending region BA may be composed of a conductive material having excellent flexibility such as gold (Au), silver (Ag), aluminum (Al), or the like, but the exemplary embodiments of the present disclosure are not limited thereto. In another example, the plurality of first connection lines 121 and the plurality of second connection lines 122 may be composed of molybdenum (Mo), chromium (Cr), titanium (Ti), nickel (Ni), neodymium (Nd), copper (Cu), an alloy of silver (Ag) and magnesium (Mg), alloys thereof, or the like, but the exemplary embodiments of the present disclosure are not limited thereto.

The fourth organic insulating layer 115d may be disposed on the plurality of first connection lines 121 and the plurality of second connection lines 122. The fourth organic insulating layer 115d may be disposed in the remaining region excluding the bending region BA, but the exemplary embodiments of the present disclosure are not limited thereto. The fourth organic insulating layer 115d may be disposed in the display region AA, the first non-display region NA1, and the second non-display region NA2. A portion of the fourth organic insulating layer 115d disposed in the bending region BA may be removed. The fourth organic insulating layer 115d may be composed of an organic insulating material, but the exemplary embodiments of the present disclosure are not limited thereto. For example, the fourth organic insulating layer 115d may be composed of a photoresist, a polyimide (PI)-based material, a photo acrylic-based material, or the like, but the exemplary embodiments of the present disclosure are not limited thereto.

The plurality of banks BNK may be disposed on the fourth organic insulating layer 115d in the display region AA. The plurality of banks BNK may be disposed to overlap the plurality of subpixels, respectively. One or more light-emitting elements ED of the same type may be disposed on each of the plurality of banks BNK.

The plurality of signal lines TL may be disposed on the fourth organic insulating layer 115d in the display region AA. The plurality of signal lines TL may be disposed in regions between the plurality of banks BNK. For example, the plurality of signal lines TL may be disposed adjacent to any one of the plurality of banks BNK.

The plurality of contact electrodes CCE may be disposed on the fourth organic insulating layer 115d in the display region AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from adjacent signal line TL toward an upper portion of the bank BNK. The first electrode CE1 may be disposed on an upper surface of the bank BNK and a side surface of the bank BNK. For example, the first electrode CE1 may be disposed to extend from the signal line TL on the upper surface of the fourth organic insulating layer 115d to the side surface of the bank BNK and the upper surface of the bank BNK.

Referring to FIGS. 8 and 9, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be composed of titanium (Ti), molybdenum (Mo), aluminum (Al), or indium tin oxide (ITO), but the exemplary embodiments of the present disclosure are not limited thereto.

According to the present disclosure, some conductive layers having excellent reflection efficiency among the plurality of conductive layers constituting the first electrode CE1 may be configured as alignment keys and/or reflective plates for aligning the light-emitting elements ED. For example, the second conductive layer CE1b among the plurality of conductive layers of the first electrode CE1 may include a reflective material. For example, the second conductive layer CE1b may include aluminum (Al), but the exemplary embodiments of the present disclosure are not limited thereto. Accordingly, the second conductive layer CE1b may be configured as a reflective plate. Further, identification in the manufacturing process may be facilitated due to the high reflective efficiency of the second conductive layer CE1b, and thus a position or transfer position of the light-emitting element ED may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, portions of the third conductive layer CE1c and fourth conductive layer CE1d disposed on the bank BNK may be removed or etched to expose an upper surface of the second conductive layer CE1b. For example, in the third conductive layer CE1c and the fourth conductive layer CE1d, center portions and edge portions where a solder pattern SDP is disposed may be left, and the remaining portion may be removed. For example, the edge portion of each of the third conductive layer CE1c made of titanium (Ti) and the fourth conductive layer CE1d made of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) having excellent adhesion to the solder pattern SDP and having corrosion resistance and acid resistance. However, the exemplary embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the exemplary embodiments of the present disclosure are not limited thereto.

According to the present disclosure, the signal line TL, the contact electrode CCE, and the pad electrode PE disposed on the same layer as the first electrode CE1 may be composed of multiple layers of a conductive material, but the exemplary embodiments of the present disclosure are not limited thereto. For example, the signal line TL, the contact electrode CCE, and the pad electrode PE may be formed of multiple layers of indium tin oxide (ITO)/titanium (Ti)/aluminum (Al)/titanium (Ti), but the exemplary embodiments of the present disclosure are not limited thereto.

According to the present disclosure, the solder pattern SDP may be disposed on the first electrode CE1 in each of the plurality of subpixels. The solder pattern SDP may bond the light-emitting element ED to the first electrode CE1. The first electrode CE1 and the light-emitting element ED may be electrically connected by eutectic bonding using the solder pattern SDP, but the exemplary embodiments of the present disclosure are not limited thereto. For example, when the solder pattern SDP is composed of indium (In) and the anode electrode 134 of the light-emitting element ED is composed of gold (Au), the solder pattern SDP and the anode electrode 134 may be bonded by applying heat and pressure during the transfer process of the light-emitting element ED. The light-emitting element ED may be bonded to the solder pattern SDP and the first electrode CE1 by eutectic bonding without a separate adhesive. For example, the solder pattern SDP may be composed of indium (In), tin (Sn), or an alloy thereof, but the exemplary embodiments of the present disclosure are not limited thereto. For example, the solder pattern SDP may be a bonding pad or a joining pad, but the exemplary embodiments of the present disclosure are not limited thereto.

Further, referring to FIG. 9, a lower insulating layer 116 may be disposed on the first electrode CE1 and the bank BNK. For example, the lower insulating layer 116 may be entirely disposed in the display region AA and the non-display region NA. The lower insulating layer 116 may be composed of a single layer or multiple layers of silicon oxide (SiOx) or silicon nitride (SiNx) which is an inorganic film material, for example, the lower insulating layer 116 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

According to the present disclosure, the lower insulating layer 116 which functions as a passivation layer may be disposed on the plurality of signal lines TL, the plurality of first electrodes CE1, the plurality of contact electrodes CCE, and the third insulating layer 115c. For example, the lower insulating layer 116 may be disposed in the display region AA, the first non-display region NA1, and the second non-display region NA2. A portion of the lower insulating layer 116 disposed in the bending region BA may be removed. A portion of the lower insulating layer 116 covering the plurality of pad electrodes PE in the second non-display region NA2 may be removed. Since the lower insulating layer 116 is disposed to cover the remaining region excluding regions where the bending region BA, the plurality of pad electrodes PE, and the solder pattern SDP are disposed, the penetration of moisture or impurities into the light-emitting element ED may be reduced or minimized. For example, the lower insulating layer 116 may be composed of a single layer or multiple layers of silicon oxide (SiOx) or silicon nitride (SiNx) which is an inorganic film material, but the exemplary embodiments of the present disclosure are not limited thereto. For example, the lower insulating layer 116 may be a protective layer or an insulating layer, but the exemplary embodiments of the present disclosure are not limited thereto. Further, the lower insulating layer 116 may include a hole which exposes the solder pattern SDP.

The light-emitting element ED may be disposed on the solder pattern SDP in each of the plurality of subpixels. The first light-emitting element 130 may be disposed in the first subpixel SP1. The second light-emitting element 140 may be disposed in the second subpixel SP2. The third light-emitting element 150 may be disposed in the third subpixel SP3. Each of the plurality of light-emitting elements 130, 140, and 150 may include one or more sub light-emitting element. For example, each of the plurality of light-emitting elements 130, 140, and 150 may include one sub light-emitting element. For example, the first light-emitting element 130 may include a 1-1 light-emitting element 130a disposed in the 1-1 sub-pixel SP1a and a 1-2 light-emitting element 130b disposed in the 1-2 sub-pixel SP1b. The second light-emitting element 140 may include a 2-1 light-emitting element 140a disposed in the 2-1 sub-pixel SP2a and a 2-2 light-emitting element 140b disposed in the 2-2 sub-pixel SP2b. The third light-emitting element 150 may include a 3-1 light-emitting element 150a disposed in the 3-1 sub-pixel SP3a and a 3-2 light-emitting element 150b disposed in the 3-2 sub-pixel SP3b. However, the disclosure is not limited thereto. For example, the plurality of light-emitting elements may include a fourth light-emitting element emitting white light. The fourth light-emitting element may also include one or more sub light-emitting element.

The first light-emitting element 130 among the first light-emitting element 130, the second light-emitting element 140, and the third light-emitting element 150 may have the largest size (e.g., a volume). The second light-emitting element 140 and the third light-emitting element 150 may have the same size. For example, the size of second light-emitting element 140 and the size of the third light-emitting element 150 are same and are smaller than that of the first light-emitting element 130, but not limited thereto.

The solder pattern SDP may have a width equal to or smaller than a width of the lower end of the first light-emitting element 130 and may have a width greater than a width of the lower end of each of the second light-emitting element 140 and the third light-emitting element 150, but the present disclosure is not limited thereto.

The light-emitting element ED may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like, but the exemplary embodiments of the present disclosure are not limited thereto.

Referring to FIGS. 8 and 9, the first light-emitting element 130 may include the anode electrode 134, a first semiconductor layer 131, an active layer 132, a second semiconductor layer 133, the cathode electrode 135, and an encapsulation film 136, but the exemplary embodiments of the present disclosure are not limited thereto. For example, the first light-emitting element 130 may not include the encapsulation film 136. The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented with a group III-V compound semiconductor, a group II-VI compound semiconductor, or the like, and may be doped with impurities (or dopant). For example, one of the first semiconductor layer 131 and the second semiconductor layer 133 may be a semiconductor layer doped with n-type impurities and the other may be a semiconductor layer doped with p-type impurities, but the exemplary embodiments of the present disclosure are not limited thereto. For example, one or more of the first semiconductor layer 131 and the second semiconductor layer 133 may be layers in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like is doped with n-type impurities or p-type impurities, but the exemplary embodiments of the present disclosure are not limited thereto. For example, the n-type impurities may be silicon (Si), germanium (Ge), selenium (Se), carbon (C), tellurium (Te), tin (Sn), or the like, but the exemplary embodiments of the present disclosure are not limited thereto. For example, the p-type impurities may be magnesium (Mg), zinc (Zn), calcium (Ca), strontium (Sr), barium (Ba), beryllium (Be), or the like, but the exemplary embodiments of the present disclosure are not limited thereto.

For example, the first semiconductor layer 131 and the second semiconductor layer 133 may be a nitride semiconductor containing n-type impurities and a nitride semiconductor containing p-type impurities, respectively, but the exemplary embodiments of the present disclosure are not limited thereto. For example, the first semiconductor layer 131 may be a nitride semiconductor containing p-type impurities, and the second semiconductor layer 133 may be a nitride semiconductor containing n-type impurities, but the exemplary embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may have any one of a single well structure, a multi-well structure, a single quantum well structure, a multi quantum well (MQW) structure, a quantum dot structure, or a quantum line structure, but the exemplary embodiments of the present disclosure are not limited thereto. For example, the active layer 132 may be composed of indium gallium nitride (InGaN) or gallium nitride (GaN), but the exemplary embodiments of the present disclosure are not limited thereto.

In another example, the active layer 132 may include a multi quantum well (MQW) structure having a well layer and a barrier layer having a higher band gap than the well layer. For example, the active layer 132 may include an InGaN well layer and an AlGaN barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be composed of a conductive material which may be eutectically bonded to the solder pattern SDP, but the exemplary embodiments of the present disclosure are not limited thereto. For example, the anode electrode 134 may be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be composed of a transparent conductive material so that light emitted from the light-emitting element ED may be directed toward an upper portion of the light-emitting element ED, but the exemplary embodiments of the present disclosure are not limited thereto. For example, the cathode electrode 135 may be composed of a material such as indium tin oxide (ITO), indium zinc oxide (IZO), or indium gallium zinc oxide (IGZO), but the exemplary embodiments of the present disclosure are not limited thereto.

The encapsulation film 136 may be disposed on at least portions of at least one of the first semiconductor layer 131, the active layer 132, the second semiconductor layer 133, the anode electrode 134, and the cathode electrode 135. For example, the encapsulation film 136 may surround at least portions of at least one of the first semiconductor layer 131, the active layer 132, the second semiconductor layer 133, the anode electrode 134, and the cathode electrode 135. For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least portions of at least one of the anode electrode 134 and the cathode electrode 135, for example, an edge portion (or one side) of the anode electrode 134 and an edge portion (or one side) of the cathode electrode 135. Since at least a portion of the anode electrode 134 may be exposed from the encapsulation film 136, the anode electrode 134 and the solder pattern SDP may be connected. For example, since at least a portion of the cathode electrode 135 may be exposed from the encapsulation film 136, the cathode electrode 135 and the second electrode CE2 may be connected. For example, the encapsulation film 136 may be formed of an insulating material such as silicon nitride (SiNx) or silicon oxide (SiOx), for example, the encapsulation film 136 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

In another example, the encapsulation film 136 may have a structure in which a reflective material is dispersed in a resin layer, but the exemplary embodiments of the present disclosure are not limited thereto. For example, the encapsulation film 136 may be manufactured as a reflector having various structures, but the exemplary embodiments of the present disclosure are not limited thereto. Since light emitted from the active layer 132 may be reflected upward by the encapsulation film 136, light extraction efficiency may be enhanced. For example, the encapsulation film 136 may be a reflective layer, but the exemplary embodiments of the present disclosure are not limited thereto.

According to the present disclosure, although the light-emitting element ED is described as having a vertical structure, the exemplary embodiments of the present disclosure are not limited thereto. For example, the light-emitting element ED may have a lateral structure or a flip chip structure.

Although the first light-emitting element 130 has been described with reference to FIG. 9, the second light-emitting element 140 and the third light-emitting element 150 may have substantially the same structure as the first light-emitting element 130. For example, the structures of the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130.

According to the present disclosure, a first optical layer 117a surrounding the plurality of light-emitting elements ED in the display region AA may be disposed on the lower insulating layer 116. For example, the first optical layer 117a may be disposed to cover the plurality of light-emitting elements ED and the plurality of banks BNK in regions of the plurality of subpixels. For example, the first optical layer 117a may cover the bank BNK, a portion of the lower insulating layer 116, and a space between the plurality of light-emitting elements ED. The first optical layer 117a may be disposed between the plurality of light-emitting elements ED included in one pixel PX and between the plurality of banks BNK or may cover spaces between the plurality of light-emitting elements ED and between the plurality of banks BNK. For example, the first optical layers 117a may extend in the first direction (X) and may be disposed spaced apart from each other in the second direction (Y). For example, the first optical layer 117a may be disposed between the lower insulating layer 116 and the second electrode CE2 to surround side portions of the light-emitting element ED and the bank BNK, but the exemplary embodiments of the present disclosure are not limited thereto. For example, the first optical layer 117a may be a diffusion layer, a sidewall diffusion layer, or the like, but the exemplary embodiments of the present disclosure are not limited thereto.

The first optical layer 117a may include an organic insulating material in which fine particles are dispersed, but the exemplary embodiments of the present disclosure are not limited thereto. For example, the first optical layer 117a may be composed of siloxane in which fine metal particles such as titanium dioxide (TiO₂) particles are dispersed, but the exemplary embodiments of the present disclosure are not limited thereto. Light from the plurality of light-emitting elements ED may be scattered by the fine particles dispersed in the first optical layer 117a and emitted to the outside of the display device 1000. Accordingly, the first optical layer 117a may enhance the extraction efficiency of the light emitted from the plurality of light-emitting elements ED.

For example, the first optical layer 117a may be disposed in each of the plurality of pixels PX or may be disposed together in some of the pixels PX disposed in the same row, but the exemplary embodiments of the present disclosure are not limited thereto. For example, the first optical layer 117a may be disposed in each of the plurality of pixels PX, or the plurality of pixels PX may share one first optical layer 117a. In another example, each of the plurality of subpixels may separately include the first optical layer 117a, but the exemplary embodiments of the present disclosure are not limited thereto.

According to the present disclosure, a second optical layer 117b may be disposed on the lower insulating layer 116 in the display region AA. For example, the second optical layer 117b may be disposed to surround the first optical layer 117a. For example, the second optical layer 117b may be in contact with a side surface of the first optical layer 117a. For example, the second optical layer 117b may be disposed in the region between the plurality of pixels PX. However, the exemplary embodiments of the present disclosure are not limited thereto. For example, the second optical layer 117b may be a diffusion layer, a diffusion layer window, a window diffusion layer, or the like, but the exemplary embodiments of the present disclosure are not limited thereto.

The second optical layer 117b may be composed of an organic insulating material, but the exemplary embodiments of the present disclosure are not limited thereto. The second optical layer 117b may be composed of the same material as the first optical layer 117a, but the exemplary embodiments of the present disclosure are not limited thereto. For example, the first optical layer 117a may include fine particles, and the second optical layer 117b may not include fine particles. For example, the second optical layer 117b may be formed of siloxane, but the exemplary embodiments of the present disclosure are not limited thereto.

For example, a thickness of the first optical layer 117a may be less than a thickness of the second optical layer 117b, but the exemplary embodiments of the present disclosure are not limited thereto. Accordingly, when viewed in a plan view, a region where the first optical layer 117a is disposed may include a concave portion recessed inward from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through contact holes of the second optical layer 117b. For example, the second electrode CE2 may be disposed on the plurality of light-emitting elements ED. For example, the second electrode CE2 may include a transparent conductive oxide such as indium tin oxide (ITO), indium zinc oxide (IZO), or the like, but the exemplary embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover an outer flat surface of the first optical layer 117a.

The second electrode CE2 may continuously extend in the first direction (X) of the substrate 110.

Accordingly, the second electrode CE2 may be connected to the plurality of pixels PX, disposed in the first direction (X) of the substrate 110, in common. For example, the second electrode CE2 may be connected to the plurality of pixels PX in common.

According to the present disclosure, the second electrode CE2 may continuously extend on the first optical layer 117a, the second optical layer 117b, and the light-emitting element ED. The region where the first optical layer 117a is disposed may include the concave portion recessed inward from the upper surface of the second optical layer 117b. Accordingly, a first portion of the second electrode CE2 disposed on the first optical layer 117a is disposed along the concave portion, and thus may be disposed at a lower position than a second portion of the second electrode CE2 disposed on the second optical layer 117b.

Further, a third optical layer 117c may be disposed on the second electrode CE2 and the first optical layer 117a. The third optical layer 117c may be disposed to overlap the plurality of light-emitting elements ED and the first optical layer 117a. Since the third optical layer 117c is disposed on the second electrode CE2 and the plurality of light-emitting elements ED, the stain (mura) which may occur over some of the plurality of light-emitting elements ED may be improved. For example, when the plurality of light-emitting elements ED are transferred onto the substrate 110 of the display device 1000, a region where intervals between the plurality of light-emitting elements ED are not uniform may occur due to a process deviation or the like. When the intervals between the plurality of light-emitting elements ED are not uniform, a light-emitting region of each of the plurality of light-emitting elements ED may be disposed non-uniformly, and the stain (mura) may be visible to the user. Accordingly, since the third optical layer 117c is configured to uniformly diffuse light over the plurality of light-emitting elements ED, it is possible to reduce the light emitted from some of the light-emitting elements ED from being visible to the user as stain (mura).

Accordingly, since the light emitted from the plurality of light-emitting elements ED is uniformly diffused by the third optical layer 117c and extracted to the outside of the display device 1000, the brightness uniformity of the display device 1000 may be enhanced.

The third optical layer 117c may be composed of an organic insulating material in which fine particles are dispersed, but the exemplary embodiments of the present disclosure are not limited thereto. For example, the third optical layer 117c may be composed of siloxane in which fine metal particles such as titanium dioxide (TiO₂) particles are dispersed, but the exemplary embodiments of the present disclosure are not limited thereto. For example, the third optical layer 117c may be composed of the same material as the first optical layer 117a, but the exemplary embodiments of the present disclosure are not limited thereto. For example, the third optical layer 117c may be a diffusion layer or an upper surface diffusion layer, but the exemplary embodiments of the present disclosure are not limited thereto.

According to the present disclosure, light from the plurality of light-emitting elements ED may be scattered by the fine particles dispersed in the third optical layer 117c and emitted to the outside of the display device 1000. The third optical layer 117c may uniformly mix light emitted from the plurality of light-emitting elements ED to further enhance the brightness uniformity of the display device 1000. Further, the light extraction efficiency of the display device 1000 may be enhanced by the light scattered from the plurality of fine particles, and accordingly, the display device 1000 may be driven at low power.

A black matrix BM may be disposed on the second electrode CE2, the first optical layer 117a, the second optical layer 117b, and the third optical layer 117c in the display region AA. For example, the black matrix BM may fill a contact hole of the second optical layer 117b. The black matrix BM is configured to cover the display region AA, and thus may reduce the color mixing of light of the plurality of subpixels and external light reflection. For example, the black matrix BM is also disposed in the contact hole by which the second electrode CE2 and the contact electrode CCE are connected, and thus may prevent light leakage between the plurality of neighboring subpixels.

For example, the black matrix BM may be composed of an opaque material, but the exemplary embodiments of the present disclosure are not limited thereto. For example, the black matrix BM may be an organic insulating material to which a black pigment or black dye is added, for example, the black matrix BM can be formed of an organic layer such as an acryl-based material, an epoxy-based material, a phenolic-based material, a polyamide-based material, or a polyimide-based material, to which a black pigment or a black dye is added, but the exemplary embodiments of the present disclosure are not limited thereto.

A cover layer (119 in FIG. 8) may be disposed on the black matrix BM in the display region AA. For example, the cover layer 119 may be composed an organic insulating material, but the exemplary embodiments of the present disclosure are not limited thereto. For example, the cover layer 119 may be composed of a photoresist, a polyimide (PI)-based material, a photo acrylic-based material, or the like, but the exemplary embodiments of the present disclosure are not limited thereto. For example, the cover layer 119 may be an overcoating layer or an insulating layer, but the exemplary embodiments of the present disclosure are not limited thereto.

The polarization layer 293 may be disposed on the cover layer 119 via a first adhesive layer 291 as shown in FIG. 1. The cover member 120 may be disposed on the polarization layer 293 via a second adhesive layer 295. For example, the first adhesive layer 291 and the second adhesive layer 295 may include an optically clear adhesive (OCA), an optically clear resin (OCR), a pressure sensitive adhesive (PSA), or the like, but the exemplary embodiments of the present disclosure are not limited thereto.

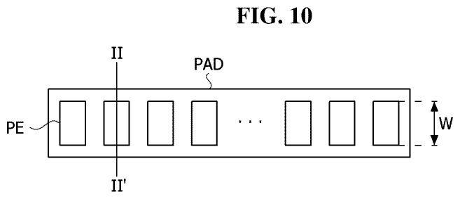

FIG. 10 is a cross-sectional view of a display device taken along line I-I′ in FIG. 2 according to one exemplary embodiment of the present disclosure. FIG. 11 is an enlarged cross-sectional view of a pad portion of the display device according to one exemplary embodiment of the present disclosure.

Referring to FIGS. 10 and 11, first to fourth organic insulating layers 115a to 115d may be disposed in the display region AA and the pad portion PAD in the second non-display region NA2 constituting the non-display region NA surrounding the display region AA. However, the present disclosure is not limited thereto.

A plurality of first connection lines 121 may each be disposed between the first to fourth organic insulating layers 115a to 115d of the display region AA. Further, a plurality of second connection lines 122 may be disposed between the first to fourth organic insulating layers 115a to 115d of the pad portion PAD of the second non-display region NA2. Here, the plurality of first connection lines 121 may include a 1-1 connection line 121a, a 1-2 connection line 121b, a 1-3 connection line 121c, and a 1-4 connection line 121d. However, the exemplary embodiments of the present disclosure are not limited thereto. The plurality of first connection lines 121a to 121d of the display region AA may be connected to the pixel driving circuit PD. Further, the pixel driving circuit PD may be electrically connected to the plurality of signal lines TL, the plurality of contact electrodes CCE, and the like through the plurality of first connection lines 121.

In addition, the plurality of second connection lines 122 may include a 2-1 connection line 122a, a 2-2 connection line 122b, a 2-3 connection line 122c, and a 2-4 connection line 122d. However, the exemplary embodiments of the present disclosure are not limited thereto. Accordingly, the signals from the flexible film (FF) and the printed circuit board through the pad electrode PE of the pad portion PAD may be transmitted to the 2-1 connection line 122a through the 2-4 connection line 122d, the 2-3 connection line 122c, and the 2-2 connection line 122b.

A plurality of pad electrodes PE may be disposed on the 2-4 connection line 122d disposed to extend from the display region AA to the pad portion PAD of the second non-display region NA2. The plurality of pad electrodes PE may be electrically connected to the 2-4 connection line (122d in FIG. 8) through contact holes of the fourth insulating layer 115d.

Referring to FIGS. 8, 10 and 11, the fourth organic insulating layer 115d may be disposed on the plurality of 1-4 connection lines 121d and the plurality of 2-4 connection lines 122d. The fourth organic insulating layer 115d may be disposed in the remaining region excluding the bending region BA, but the exemplary embodiments of the present disclosure are not limited thereto. Specifically, the fourth organic insulating layer 115d may be disposed in the display region AA, and the pad portion PAD of the first non-display region NA1 and the second non-display region NA2, but the exemplary embodiments of the present disclosure are not limited thereto. Here, the fourth organic insulating layer 115d may include a 4-1 organic insulating layer 115d-1 disposed within the display region AA and a 4-2 organic insulating layer 115d-2 disposed in the pad portion PAD.

Accordingly, since the 4-2 organic insulating layer 115d-2 is formed in the pad portion PAD, line defects, for example, damage to the side surface of the connection line under the pad electrode PE, and a residual film, corrosion, and the like of the metal layer of the pad electrode PE may be improved. Specifically, as the 4-2 organic insulating layer 115d-2 in the pad portion PAD covers a side surface of the 2-4 connection line 122d, a portion of the 4-2 organic insulating layer 115d-2 blocks outgassing from a lower portion, and thus may suppress the occurrence of the residual film and corrosion of the metal layer.

Further, among the fourth organic insulating layers 115d, a thickness t2 of the 4-2 organic insulating layer 115d-2 located in the pad portion PAD may be formed lower than a thickness t1 of the 4-1 organic insulating layer 115d-1. Since a portion of the 4-2 insulation layer 115d-2 supports the side surface of the pad electrode PE, the deterioration of the pressing of the conductive ball 300 applied to connect the circuit board on the pad electrode PE may be minimized or reduced. However, the present disclosure is not limited thereto.

Referring to FIG. 8, an adhesive layer ACF may be disposed on the plurality of pad electrodes PE provided in the pad portion PAD. The adhesive layer ACF may be an adhesive layer in which conductive balls (300 in FIG. 8) are dispersed in an insulating material, but the exemplary embodiments of the present disclosure are not limited thereto. When heat or pressure is applied to the adhesive layer ACF, since the conductive balls (300 in FIG. 8) may be electrically connected at a portion to which the heat or pressure is applied, the adhesive layer ACF may have conductive properties. The flexible circuit board (or flexible film) CB may be attached or bonded to the plurality of pad electrodes PE by disposing the conductive balls 300 between the plurality of pad electrodes PE and a circuit board, for example, the flexible circuit board (or flexible film) CB or the printed circuit board 160. For example, the conductive balls 300 may be included in an anisotropic conductive film (ACF), but the exemplary embodiments of the present disclosure are not limited thereto.

Further, the circuit board, for example, the flexible circuit board (or flexible film) CB or the printed circuit board 160 may be disposed on the conductive balls 300. However, the present disclosure is not limited thereto. The flexible circuit board (or flexible film) CB or the printed circuit board 160 may be electrically connected to the plurality of pad electrodes PE through the conductive balls 300. Accordingly, the signals output from the flexible circuit board (or flexible film) CB and the printed circuit board (160 in FIG. 1) may be transmitted to the pixel driving circuit PD of the display region AA through the plurality of pad electrodes PE, the 2-4 connection line (122d in FIG. 8), the 2-3 connection line (122c in FIG. 8), the 2-2 connection line (122b in FIG. 8), and the 2-1 connection line (122a in FIG. 8).

Specifically, referring to FIGS. 10 and 11, the plurality of pad electrodes PE may be disposed in the pad portion PAD located in the second non-display region NA2 of the substrate 110. The plurality of pad electrodes PE may be disposed on the 2-4 connection line 122d extending from the 1-4 connection line 121d of the display region AA and located in the pad portion PAD. In this case, the plurality of pad electrodes PE may be formed simultaneously with the first electrode CE1. The first electrode CE1 may be composed of a plurality of conductive layers. For example, referring to FIG. 9, the first electrode CE1 may include the first conductive layer CE1a, the second conductive layer CE1b, the third conductive layer CE1c, and the fourth conductive layer CE1d, but the exemplary embodiments of the present disclosure are not limited thereto.

Referring to FIGS. 8 and 11, the fourth organic insulating layer 115d may be formed on the third organic insulating layer 115c. Referring to FIG. 11, the 4-1 organic insulating layer 115d-1 may cover at least a portion of an upper surface of the third organic insulating layer 115c and side surfaces and at least a portion of an upper surface of the 2-4 connection line 122d. Referring to FIG. 8, among the fourth organic insulating layers 115d, a first contact hole 115d-1a which exposes an upper surface of the 1-4 connection line 121d may be formed in the 4-1 organic insulating layer 115d-1 located in the display region AA.

Here, the thickness t1 of the 4-1 organic insulating layer 115d-1 may be maintained the same as the thickness of the fourth organic insulating layer 115d. Further, the first electrode CE1 or the contact electrode CCE in the display region AA may be electrically connected to the 1-4 connection line 121d through the first contact hole 115d-1a.

In addition, a second contact hole 115d-2a which exposes an upper surface of the 2-4 connection line 122d may be formed in the 4-2 organic insulating layer 115d-2 located in the pad portion PAD. Here, the 4-2 organic insulating layer 115d-2 may be disposed on the third organic insulating layer 115c. Here, the 4-2 organic insulating layer 115d-2 may be disposed to cover the entire side surface and a portion of the upper surface of the 2-4 connection line 122d. Accordingly, since a portion of the 4-2 organic insulating layer 115d-2 covers the side surface of the 2-4 connection line 122d and thus the 2-4 connection line 122d may not be exposed to the outside, metal deformation of the metal layer caused by outgassing may not occur when the metal layer for forming the pad electrode is deposited.

Accordingly, when the metal layer for forming the pad electrode is deposited, for example, an oxide layer such as TiOx or AlOx may not be formed, and thus, a residual film due to the non-etching of the oxide layer such as TiOx or AlOx when the metal layer is etched may not be generated. Furthermore, according to the present disclosure, a corrosion phenomenon caused by the deterioration of processing capability after an etching process due to outgassing may not occur.

Further, the thickness t2 of the 4-2 organic insulating layer 115d-2 of the pad portion PAD may be formed to be thinner than the thickness t1 of the 4-1 organic insulating layer 115d-1. In addition, the pad electrode PE may be electrically connected to the 2-4 connection line 122d through the second contact hole 115d-2a. Accordingly, since a portion of the 4-2 organic insulating layer 115d-2 under the pad portion PAD is formed with a lower thickness than the 4-1 organic insulating layer 115d-1 under the display region AA, a pressing phenomenon of the conductive ball on the pad electrode PE may be minimized or reduced.

Further, as the conductive balls (300 in FIG. 8) are disposed on the exposed upper surfaces of the plurality of pad electrodes PE and the circuit board, for example, the flexible circuit board CB or the printed circuit board 160 is disposed thereon, the plurality of pad electrodes PE and the circuit board may be electrically connected.

For example, bumps (not shown) provided on the lower end of the circuit board may be bonded to the pad electrode PE and may be electrically connected to the pad electrode PE by an anisotropic conductive film (ACF). That is, as the conductive balls 300 included in the anisotropic conductive film simultaneously come into contact with the pad electrodes PE and the bumps, the pad electrodes PE and the circuit board may be electrically connected.

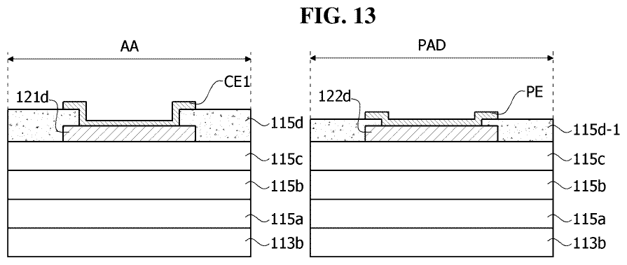

FIG. 12 is a cross-sectional view of a display device taken along line II-II′ in FIG. 10 according to another exemplary embodiment of the present disclosure. FIG. 13 is an enlarged cross-sectional view of a pad portion of the display device according to another exemplary embodiment of the present disclosure.

According to the exemplary embodiment of the present disclosure, as shown in FIGS. 12 and 13, the same configurations as one exemplary embodiment of the present disclosure in FIGS. 10 and 11 excluding a configuration in which a thickness t2 of the 4-2 organic insulating layer 115d-2 is formed with the same height as a layer thickness of the 2-4 connection line 122d may be included. Hereinafter, the description will focus on the configuration in which the thickness t2 of the 4-2 organic insulating layer 115d-2 is formed with the same height as the layer thickness of the 2-4 connection line 122d with reference to FIGS. 12 and 13.

Referring to FIGS. 12 and 13, a plurality of pad electrodes PE may be disposed in the pad portion PAD located in the second non-display region NA2 of the substrate 110. The plurality of pad electrodes PE may be disposed on the 2-4 connection lines 122d extending from the 1-4 connection lines 121d of the display region AA and located in the pad portion PAD. In this case, the plurality of pad electrodes PE may be formed simultaneously with the first electrode CE1. The first electrode CE1 may be formed of a plurality of conductive layers. For example, referring to FIG. 9, the first electrode CE1 may include a first conductive layer CE1a, a second conductive layer CE1b, a third conductive layer CE1c, and a fourth conductive layer CE1d, but the exemplary embodiments of the present disclosure are not limited thereto.

Referring to FIGS. 12 and 13, a fourth organic insulating layer 115d may be formed on the third organic insulating layer 115c. Referring to FIG. 12, the 4-2 organic insulating layer 115d-2 may cover at least a portion of an upper surface of the third organic insulating layer 115c and side surfaces of the 2-4 connection line 122d. Among the fourth organic insulating layers 115d, a first contact hole 115d-1a which exposes an upper surface of the 1-4 connection line 121d may be formed in a 4-1 organic insulating layer 115d-1 located in the display region AA.

Here, a thickness t1 of the 4-1 organic insulating layer 115d-1 may be maintained the same as the thickness of the fourth organic insulating layer 115d. Further, the first electrode CE1 or the contact electrode CCE in the display region AA may be electrically connected to the 1-4 connection line 121d through the first contact hole 115d-1a.

Further, a 4-2 organic insulating layer 115d-2 located in the pad portion PAD may be disposed to cover the side surface of the 2-4 connection line 122d. That is, the 4-2 organic insulating layer 115d-2 is not disposed on an upper surface of the 2-4 connection line 122d. Further, the thickness t2 of the 4-2 organic insulating layer 115d-2 may be formed to be the same as the thickness of the 2-4 connection line 122d.

Accordingly, since the portion of the 4-2 organic insulating layer 115d-2 covers the side surface of the 2-4 connection line 122d and thus the 2-4 connection line 122d may not be exposed to the outside, metal deformation of the metal layer caused by outgassing may not occur when the metal layer for forming the pad electrode is deposited.

Accordingly, when the metal layer for forming the pad electrode is deposited, for example, an oxide layer such as TiOx or AlOx may not be formed, and thus a residual film due to the non-etching of the oxide layer such as TiOx or AlOx when the metal layer is etched may not be generated. Furthermore, according to the present disclosure, a corrosion phenomenon caused by the deterioration of processing capability after an etching process due to outgassing may not occur.

Further, the thickness t2 of the 4-2 organic insulating layer 115d-2 of the pad portion PAD may be formed to be thinner than the thickness t1 of the 4-1 organic insulating layer 115d-1. In addition, the pad electrode PE may be electrically and directly connected to the 2-4 connection line 122d. Accordingly, since a portion of the 4-2 organic insulating layer 115d-2 under the pad portion PAD is formed with a lower thickness than the 4-1 organic insulating layer 115d-1 under the display region AA, a pressing phenomenon of the conductive ball on the pad electrode PE may be minimized.

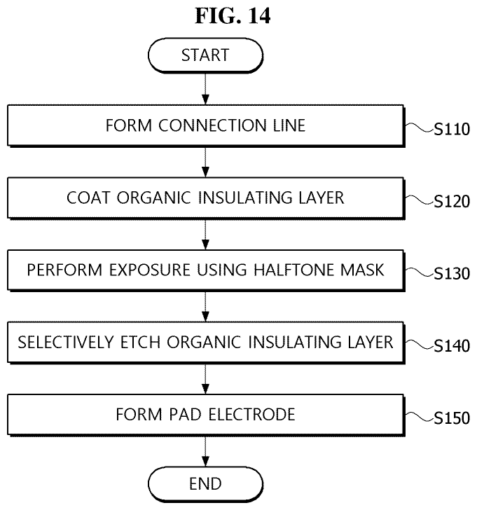

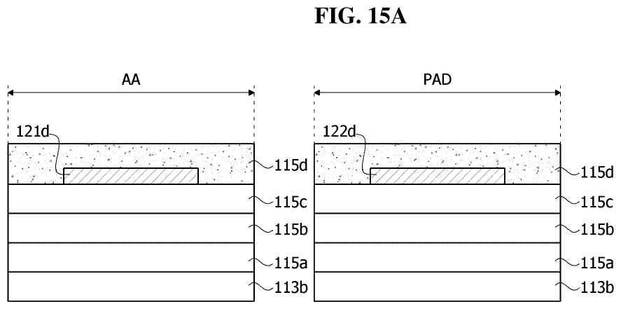

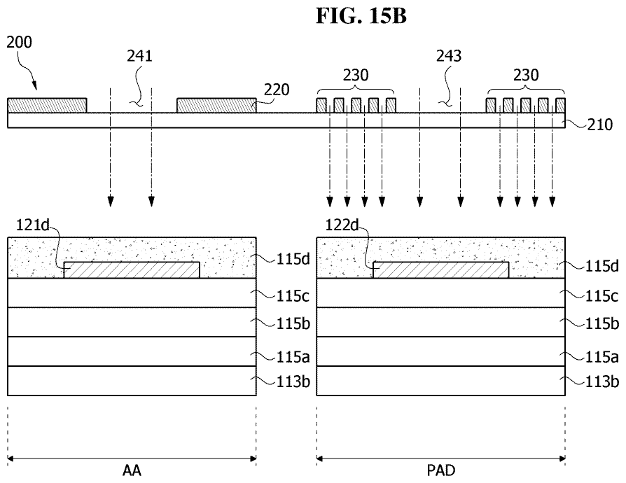

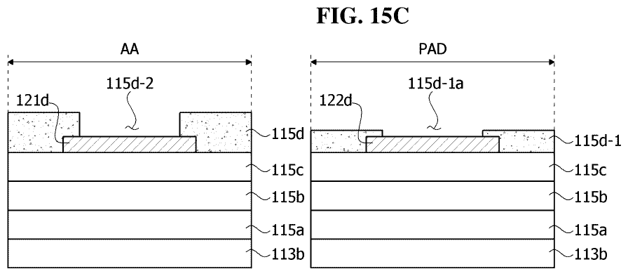

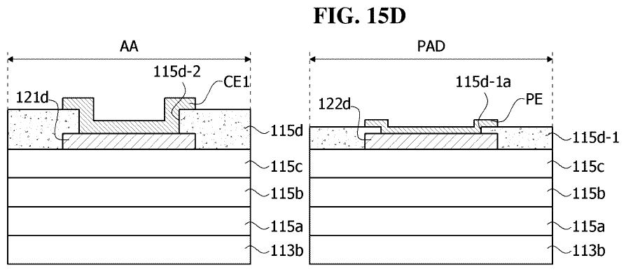

FIG. 14 is a flowchart of a display device manufacturing process according to an exemplary embodiment of the present disclosure. FIGS. 15A, 15B, 15C and 15D are cross-sectional views of a display device manufacturing process according to one exemplary embodiment of the present disclosure.

As a first operation S110, referring to FIG. 15A, first to third organic insulating layers 115a to 115c may be disposed in the display region AA and the pad portion PAD in the second non-display region NA2 constituting the non-display region NA surrounding the display region AA. However, the present disclosure is not limited thereto.

In this case, a plurality of first connection lines 121 may each be disposed between the first to the third organic insulating layers 115a to 115c of the display region AA. Further, a plurality of second connection lines 122 may be disposed between the first to third organic insulating layers 115a to 115c of the pad portion PAD of the second non-display region NA2.

Here, the plurality of first connection lines 121 may include a 1-1 connection line 121a, a 1-2 connection line 121b, a 1-3 connection line 121c, and a 1-4 connection line 121d. However, the exemplary embodiments of the present disclosure are not limited thereto. The plurality of first connection lines 121a to 121d of the display region AA may be connected to the pixel driving circuit (PD in FIG. 8). Further, the pixel driving circuit PD may be electrically connected to the plurality of signal lines TL, the plurality of contact electrodes CCE, and the like through the plurality of first connection lines 121.

In addition, the plurality of second connection lines 122 may include a 2-1 connection line 122a, a 2-2 connection line 122b, a 2-3 connection line 122c, and a 2-4 connection line 122d. However, the exemplary embodiments of the present disclosure are not limited thereto.

Next, the 1-4 connection line 121d and the 2-4 connection line 122d may be disposed on the third organic insulating layer 115c. The 1-4 connection line 121d may be located in the display region AA, and the 2-4 connection line 122d may be located in the pad portion PAD of the non-display region NA.

Subsequently, as a second operation S120, referring to FIG. 15A, a fourth organic insulating layer 115d may be disposed on the 1-4 connection lines 121d and the plurality of 2-4 connection lines 122d. The fourth organic insulating layer 115d may be disposed in the remaining region excluding the bending region BA, but the exemplary embodiments of the present disclosure are not limited thereto. Specifically, the fourth organic insulating layer 115d may be disposed in the display region AA, the first non-display region NA1, and the pad portion PAD of the second non-display region NA2, but the exemplary embodiments of the present disclosure are not limited thereto. Further, the fourth organic insulating layer 115d may include a 4-1 organic insulating layer 115d-1 disposed in the display region AA and a 4-2 organic insulating layer 115d-2 disposed in the pad portion PAD.

In this case, since the 4-2 organic insulating layer 115d-2 is formed on the side surface and the upper surface of the 2-4 connection lines 122d under the pad portion PAD, line defects, for example, damage to the side surface of the connection line under the pad electrode PE, and a residual film, corrosion, and the like of the metal layer of the pad electrode PE may be improved. Specifically, as the 4-2 organic insulating layer 115d-2 in the pad portion PAD covers the side surface of the 2-4 connection line 122d, the portion of the 4-2 organic insulating layer 115d-2 blocks outgassing from a lower portion, and thus may suppress the occurrence of the residual film and corrosion of the metal layer.

Subsequently, as a third operation S130, referring to FIG. 15B, a halftone mask 200 may be disposed above the display region AA and the pad portion PAD. However, the present disclosure is not limited thereto. The halftone mask 200 may include a transparent substrate 210, and a light blocking layer 220, a semi-transmission layer 230, and transmission regions 241 and 243 disposed on the transparent substrate 210. In this case, the light blocking layer 220 may be located above the display region AA and the semi-transmission layer 230 may be located above the pad portion PAD.

The transmission region 241 may be located above the 1-4 connection lines 121d of the display region AA, and the transmission region 243 may be located above the 2-4 connection line 122d of the pad portion PAD. Accordingly, light may not be transmitted through the light blocking layer 220, and only some light may be transmitted through the semi-transmission layer 230. Further, light may be entirely transmitted through the transmission regions 241 and 243. Accordingly, an amount of light to be transmitted for each region may be differentially adjusted through the halftone mask 200 so that the fourth organic insulating layer 115d is exposed.

Next, an exposure process using the halftone mask 200 may be performed. In this case, a portion of the fourth organic insulating layer 115d located under the transmission regions 241 and 243 may be exposed, and a portion of the fourth organic insulating layer 115d located under the semi-transmission layer 230 may be partially exposed. Further, a portion of the fourth organic insulating layer 115d located under the light blocking layer 220 may not be exposed.

Subsequently, as a fourth operation S140, referring to FIG. 15C, the exposed portions of the fourth organic insulating layer 115d may be selectively removed via a developing process. In this case, in the portion of the fourth organic insulating layer 115d-1 located in the display region AA, there is no change in the layer thickness t1, and a first contact hole 115d-1a which exposes the upper surface of the 1-4 connection line 121d may be formed.

Further, in the portion of the fourth organic insulating layer 115d-2 located in the pad portion PAD, the layer (thickness t2) is partially etched, and a second contact hole 115d-2a which exposes the upper surface of the 2-4 connection line 122d may be formed. In this case, the portion of the fourth organic insulating layer 115d-2 is etched by a partial thickness, and thus may have the layer thickness t2 thinner than the layer thickness t1 of the fourth organic insulating layer 115d-1 of the display region AA.

Accordingly, since the portion of the 4-2 organic insulating layer 115d-2 under the pad portion PAD is formed with a lower thickness than the 4-1 organic insulating layer 115d-1 under the display region AA, the pressing phenomenon of the conductive ball on the pad electrode PE may be minimized or reduced.

Accordingly, since the portion of the 4-2 organic insulating layer 115d-2 covers the side surface of the 2-4 connection line 122d and thus the 2-4 connection line 122d may not be exposed to the outside, metal deformation of the metal layer caused by outgassing may not occur when the metal layer for forming the pad electrode is deposited.

Accordingly, when the metal layer for forming the pad electrode is deposited, for example, an oxide layer such as TiOx or AlOx may not be formed, and thus a residual film due to the non-etching of the oxide layer such as TiOx or AlOx when the metal layer is etched may not be generated. Furthermore, according to the present disclosure, a corrosion phenomenon caused by the deterioration of processing capability after an etching process due to outgassing may not occur.

Subsequently, as a fifth operation S150, referring to FIG. 15D, the metal layer may be deposited on the 4-1 organic insulating layer 115d-1 including the first contact hole 115d-1a on the 1-4 connection line 121d of the display region AA and the 4-2 organic insulating layer 115d-2 including the second contact hole 115d-2a on the 2-4 connection lines 122d of the pad portion PAD.

Next, a first electrode CE1 and a pad electrode PE respectively connected to the 1-4 connection lines 121d and the 2-4 connection lines 122d through the first and second contact holes 115d-1a and 115d-2a may be formed by selectively removing the metal layer by a mask process using a photolithography technique. In this case, the pad electrode PE may be brought in contact with the upper surface of the 2-4 connection line 122d, a side surface of the second contact hole 115d-2a, and a portion of the upper surface of the fourth organic insulating layer 115d-2.

Subsequently, an adhesive layer ACF may be disposed on the plurality of pad electrodes PE provided on the pad portion PAD. The adhesive layer ACF may be an adhesive layer in which conductive balls (300 in FIG. 8) are dispersed in an insulating material, but the exemplary embodiments of the present disclosure are not limited thereto. When heat or pressure is applied to the adhesive layer ACF, since the conductive balls (300 in FIG. 8) may be electrically connected at a portion to which the heat or pressure is applied, the adhesive layer ACF may have conductive properties. The flexible circuit board (or flexible film) CB may be attached or bonded to the plurality of pad electrodes PE by disposing the conductive balls 300 between the plurality of pad electrodes PE and the circuit board, for example, the flexible circuit board (or flexible film) CB or the printed circuit board 160. For example, the conductive ball 300 may be included in an anisotropic conductive film (ACF), but the exemplary embodiments of the present disclosure are not limited thereto.

Further, the circuit board, for example, the flexible circuit board (or flexible film) CB or the printed circuit board 160 may be disposed on the conductive balls 300. However, the present disclosure is not limited thereto. The flexible circuit board (or flexible film) CB or the printed circuit board 160 may be electrically connected to the plurality of pad electrodes PE through the conductive balls 300. Accordingly, the signals output from the flexible circuit board (or flexible film) CB and the printed circuit board (160 in FIG. 1) may be transmitted to the pixel driving circuit PD of the display region AA through the plurality of pad electrodes PE, the 2-4 connection line (122d in FIG. 8), the 2-3 connection line (122c in FIG. 8), the 2-2 connection line (122b in FIG. 8), and the 2-1 connection line (122a in FIG. 8).

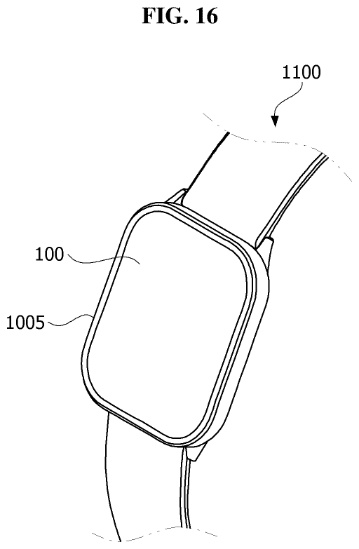

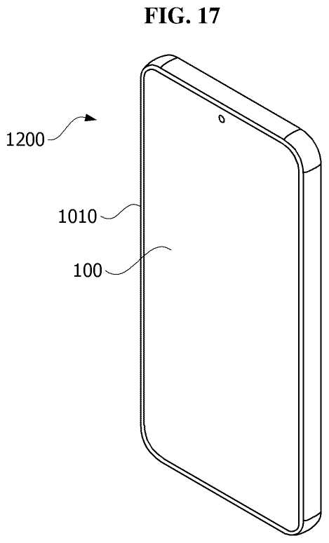

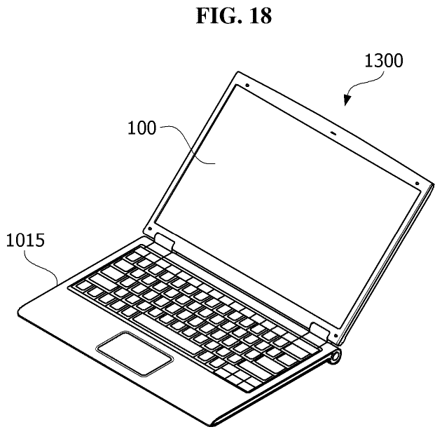

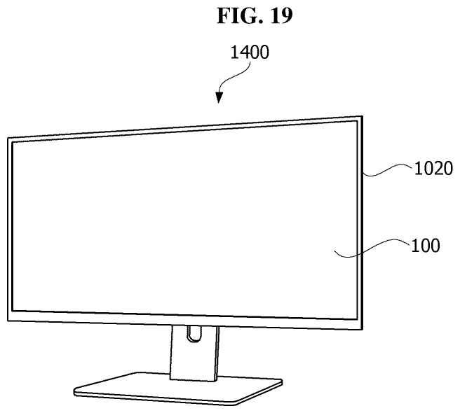

FIGS. 16, 17, 18 and 19 are views showing devices to which the display device according to exemplary embodiments of the present disclosure is applied.

Referring to FIGS. 16 to 19, the display device 1000 according to the exemplary embodiments of the present disclosure may be included in various devices or electronic devices. For example, referring to FIGS. 16 to 19, various electronic devices may include a wearable device 1100, a mobile device 1200, a notebook 1300, and a monitor or television (TV) 1400, but the exemplary embodiments of the present disclosure are not limited thereto.

The wearable device 1100, the mobile device 1200, the notebook 1300, and the monitor or TV 1400 may respectively include case portions 1005, 1010, 1015, and 1020, and the above-described display panel 100 and display device 1000 according to the exemplary embodiments of the present disclosure described in FIGS. 1 to 15D.

The display device according to the exemplary embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop personal computer (PC), a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more exemplary embodiments of the present disclosure may be applied to an organic light emitting lighting device or an inorganic light emitting lighting device.

According to the present disclosure, damage to a connection line and residual film and corrosion problems of a pad can be improved by adding an insulating layer to a pad portion, and the problem of conductive ball pressing can be minimized by forming a thickness of the insulating layer to be thinner than that of an insulating layer of a display region.

The effects according to the present disclosure are not limited to the above-mentioned effects, and other effects which are not mentioned can be clearly understood by those skilled in the art from the disclosure to be described below.

The display device according to various exemplary embodiments of the present disclosure may be described as follows.

A display device according to various exemplary embodiments of the present disclosure may comprise a substrate having a display region and a non-display region outside the display region; a circuit layer including a plurality of lines disposed on the substrate and separated with a first insulating layer therebetween; and a second insulating layer including a first contact hole that exposes an uppermost layer line in the display region and a second contact hole that exposes an uppermost layer line in the non-display region, wherein a thickness of the second insulating layer in the non-display region is different from a thickness of the second insulating layer in the display region.

According to a display device of the present disclosure, the second insulating layer may include an organic insulating material.

According to a display device of the present disclosure, the second insulating layer may cover a side surface and a portion of an upper surface of the uppermost layer line of the second contact hole.

According to a display device of the present disclosure, the display device may further include a pad electrode that covers the side surface and the portion of the upper surface of the uppermost layer line of the second contact hole.

According to a display device of the present disclosure, the second insulating layer may cover a side surface of the pad electrode and is not present on an upper surface of the pad electrode.

According to a display device of the present disclosure, the second insulating layer may have the same height as the pad electrode.

According to a display device of the present disclosure, the display device may further include a plurality of conductive balls disposed on an upper surface of the pad electrode; and a circuit board in contact with the plurality of conductive balls to be electrically connected to at least one of the plurality of pad electrodes.

According to a display device of the present disclosure, the display device may further include a plurality of light-emitting elements disposed on the substrate and electrically connected to first electrodes; a plurality of banks that support the plurality of light-emitting elements; an optical layer disposed on side surfaces of the plurality of banks and the plurality of light-emitting elements; and a plurality of signal lines that electrically connect the first electrodes and the circuit layer.

According to a display device of the present disclosure, the first electrodes include a plurality of conductive layers.

According to a display device of the present disclosure, the plurality of conductive layers includes a first conductive layer, a second conductive layer, a third conductive layer, and a fourth conductive layer, wherein each of the first conductive layer and the third conductive layer includes titanium Ti or molybdenum Mo, wherein the second conductive layer includes aluminum Al, and wherein the fourth conductive layer includes a transparent conductive oxide.

According to a display device of the present disclosure, the transparent conductive oxide includes indium tin oxide ITO or indium zinc oxide IZO.

According to a display device of the present disclosure, the optical layer includes a first optical layer including fine particles, and a second optical layer not including fine particles.

According to a display device of the present disclosure, the first optical layer is composed of siloxane in which titanium dioxide TiO2 particles are dispersed, and wherein the second optical layer is formed of siloxane.

According to a display device of the present disclosure, the display device may further include a plurality of contact electrodes electrically connected to the circuit layer; and one or more second electrodes disposed on the light-emitting elements and the optical layer, and electrically connected to the plurality of contact electrodes.

A display device according to various exemplary embodiments of the present disclosure may comprise a substrate having a display region and a non-display region outside the display region; and a circuit layer including a plurality of lines disposed on the substrate and separated with a first insulating layer therebetween, wherein a thickness of a second insulating layer that covers an uppermost layer line among the lines varies between the display region and the non-display region.

According to a display device of the present disclosure, the thickness of the second insulating layer in the non-display region may be smaller than the thickness of the second insulating layer in the display region.

According to a display device of the present disclosure, a step may be present in the second insulating layer at a boundary between the display region and the non-display region.

According to a display device of the present disclosure, the second insulating layer may cover a side surface and a portion of an upper surface of the uppermost layer line in the non-display region, or covers a side surface of the uppermost layer line.

According to a display device of the present disclosure, the display device may further include a pad electrode disposed on the uppermost layer line.

According to a display device of the present disclosure, the second insulating layer may have the same height as the pad electrode.

According to a display device of the present disclosure, the display device may further include a plurality of conductive balls disposed on an upper surface of the pad electrode; and a circuit board in contact with the plurality of conductive balls to be electrically connected to at least one of the plurality of pad electrodes.

According to a display device of the present disclosure, the display device may further include a plurality of light-emitting elements disposed on the substrate and electrically connected to first electrodes; a plurality of banks that support the plurality of light-emitting elements; an optical layer disposed on side surfaces of the plurality of banks and the plurality of light-emitting elements; and a plurality of signal lines that electrically connect the first electrodes and the circuit layer.

According to a display device of the present disclosure, the display device may further include a plurality of contact electrodes electrically connected to the circuit layer; and one or more second electrodes disposed on the light-emitting elements and the optical layer, and electrically connected to the plurality of contact electrodes.

According to a display device of the present disclosure, the thickness of the second insulating layer in the non-display region may be smaller than the thickness of the second insulating layer in the display region.

According to a display device of the present disclosure, provided is a manufacturing method of a display device, comprising: forming a substrate having a display region and a non-display region outside the display region; forming a circuit layer including a plurality of lines on the substrate, the plurality of lines being separated with a first insulating layer therebetween; and forming a second insulating layer above the plurality of lines, and the second insulating layer including a first contact hole that exposes an uppermost layer line in the display region and a second contact hole that exposes an uppermost layer line in the non-display region, wherein a thickness of the second insulating layer in the non-display region is different from a thickness of the second insulating layer in the display region.

According to a display device of the present disclosure, provided is a manufacturing method of a display device, comprising: forming a substrate having a display region and a non-display region outside the display region; and forming a circuit layer including a plurality of lines on the substrate, the plurality of lines being separated with a first insulating layer therebetween, wherein a thickness of a second insulating layer that covers an uppermost layer line among the plurality of lines varies between the display region and the non-display region.

Although exemplary embodiments of the present disclosure have been described in more detail with reference to the accompanying drawings, the present disclosure is not necessarily limited to the exemplary embodiments, and various modifications may be carried out without departing from the technical spirit of the present disclosure.

Therefore, the exemplary embodiments disclosed in the present disclosure are not intended to limited the technical spirit of the present disclosure, but intended to describe the same, and the scope of the technical spirit of the present disclosure is not limited by these exemplary embodiments. Therefore, it should be understood that the above-described exemplary embodiments are illustrative and not restrictive in all respects.

What is claimed is:

1. A display device comprising:
a substrate having a display region and a non-display region that is outside the display region;
a circuit layer including a plurality of lines on the substrate, the plurality of lines separated with a first insulating layer therebetween; and
a second insulating layer above the plurality of lines, the second insulating layer including a first contact hole that exposes an uppermost layer line in the display region and a second contact hole that exposes an uppermost layer line in the non-display region,
wherein a thickness of the second insulating layer in the non-display region is different from a thickness of the second insulating layer in the display region.

2. The display device of claim 1, wherein the second insulating layer includes an organic insulating material.

3. The display device of claim 1, wherein the second insulating layer covers a side surface and a portion of an upper surface of the uppermost layer line of the second contact hole.

4. The display device of claim 3, further comprising:
a pad electrode that covers the side surface and the portion of the upper surface of the uppermost layer line of the second contact hole.

5. The display device of claim 4, wherein the second insulating layer covers a side surface of the pad electrode and is not disposed on an upper surface of the pad electrode.

6. The display device of claim 5, wherein the second insulating layer has a same height as the pad electrode.

7. The display device of claim 4, further comprising:
a plurality of conductive balls on an upper surface of the pad electrode; and
a circuit board in contact with the plurality of conductive balls, the circuit board electrically connected to at least one pad electrode.

8. The display device of claim 1, further comprising:
a plurality of light-emitting elements on the substrate, the plurality of light-emitting elements electrically connected to first electrodes;
a plurality of banks that support the plurality of light-emitting elements;
an optical layer on side surfaces of the plurality of banks and side surfaces of the plurality of light-emitting elements; and
a plurality of signal lines that electrically connect the first electrodes and the circuit layer.

9. The display device of claim 8, wherein the first electrodes include a plurality of conductive layers.

10. The display device of claim 9, wherein the plurality of conductive layers include a first conductive layer, a second conductive layer, a third conductive layer, and a fourth conductive layer, and
wherein each of the first conductive layer and the third conductive layer includes titanium or molybdenum, the second conductive layer includes aluminum, and the fourth conductive layer includes a transparent conductive oxide.

11. The display device of claim 10, wherein the transparent conductive oxide includes indium tin oxide or indium zinc oxide.

12. The display device of claim 8, wherein the optical layer includes a first optical layer including fine particles and a second optical layer that lacks fine particles.

13. The display device of claim 12, wherein the first optical layer includes siloxane and titanium dioxide particles dispersed in the siloxane and the second optical layer includes siloxane.

14. The display device of claim 8, further comprising:
a plurality of contact electrodes electrically connected to the circuit layer; and
one or more second electrodes on the plurality of light-emitting elements and the optical layer, the one or more second electrodes electrically connected to the plurality of contact electrodes.

15. The display device of claim 1, wherein the thickness of the second insulating layer in the non-display region is less than the thickness of the second insulating layer in the display region.

16. A display device comprising:
a substrate having a display region and a non-display region that is outside the display region; and
a circuit layer including a plurality of lines on the substrate, the plurality of lines separated with a first insulating layer therebetween,
wherein a thickness of a second insulating layer that covers an uppermost layer line among the plurality of lines varies between the display region and the non-display region.

17. The display device of claim 16, wherein the second insulating layer includes an organic insulating material.

18. The display device of claim 16, wherein the thickness of the second insulating layer in the non-display region is less than the thickness of the second insulating layer in the display region.

19. The display device of claim 16, wherein a step is present in the second insulating layer at a boundary between the display region and the non-display region.

20. The display device of claim 16, wherein the second insulating layer covers a side surface and a portion of an upper surface of the uppermost layer line in the non-display region or covers a side surface of the uppermost layer line.

21. The display device of claim 16, further comprising:
a pad electrode on the uppermost layer line.

22. The display device of claim 21, wherein the second insulating layer has a same height as the pad electrode.

23. The display device of claim 21, further comprising:
a plurality of conductive balls on an upper surface of the pad electrode; and
a circuit board in contact with the plurality of conductive balls, the circuit board electrically connected to at least one pad electrode.

24. The display device of claim 16, further comprising:
a plurality of light-emitting elements on the substrate, the plurality of light-emitting elements electrically connected to first electrodes;
a plurality of banks that support the plurality of light-emitting elements;
an optical layer on side surfaces of the plurality of banks and side surfaces of the plurality of light-emitting elements; and
a plurality of signal lines that electrically connect the first electrodes and the circuit layer.

25. The display device of claim 24. further comprising:
a plurality of contact electrodes electrically connected to the circuit layer; and
one or more second electrodes on the plurality of light-emitting elements and the optical layer, the one or more second electrodes electrically connected to the plurality of contact electrodes.
